(19) United States
(12) Patent Application Publication
(10) Pub. No.: US 2024/0121938 A1
(43) Pub. Date: Apr. 11, 2024

(54) 3D MEMORY CELLS AND ARRAY ARCHITECTURES AND PROCESSES

(71) Applicant: NEO Semiconductor, Inc., San Jose, CA (US)

(72) Inventors: Fu-Chang Hsu, San Jose, CA (US); Richard J. Huang, Fremont, CA (US)

(21) Appl. No.: 18/544,393

(22) Filed: Dec. 18, 2023

Related U.S. Application Data
Application No. 18/311,212 is a continuation-in-part of application No. 17/937,432, filed on Sep. 30, 2022.
Application No. 17/937,432 is a continuation-in-part of application No. 18/311,212, filed on May 2, 2023.
(60) Provisional application No. 63/398,807, filed on Aug. 17, 2022.
(60) Provisional application No. 63/406,255, filed on Sep. 14, 2022.
(60) Provisional application No. 63/413,493, filed on Oct. 5, 2022.
(60) Provisional application No. 63/418,698, filed on Oct. 24, 2022.
(60) Provisional application No. 63/445,670, filed on Feb. 14, 2023.
(60) Provisional application No. 63/445,672, filed on Feb. 14, 2023.
(60) Provisional application No. 63/449,938, filed on Mar. 3, 2023.
(60) Provisional application No. 63/458,059, filed on Apr. 7, 2023.
(60) Provisional application No. 63/460,289, filed on Apr. 18, 2023.
(60) Provisional application No. 63/398,807, filed on Aug. 17, 2022.
(60) Provisional application No. 63/295,874, filed on Jan. 1, 2022.
(60) Provisional application No. 63/291,380, filed on Dec. 18, 2021.
(60) Provisional application No. 63/254,841, filed on Oct. 12, 2021.
(60) Provisional application No. 63/251,583, filed on Oct. 1, 2021.
(60) Provisional application No. 63/544,018, filed on Oct. 13, 2023.
(60) Provisional application No. 63/544,326, filed on Oct. 16, 2023.
(60) Provisional application No. 63/609,879, filed on Dec. 14, 2023.

(51) Int. Cl. H10B 12/00

(52) U.S. Cl. CPC H10B 12/20; H10B 12/01

(57) ABSTRACT

Various 3D memory cells, array architectures, and processes are disclosed. In an embodiment, a memory cell structure is provided that is formed by a process of alternately depositing multiple semiconductor layers and sacrificial layers to form a stack, forming vertical bit line holes through the stack using a deep trench process, forming floating bodies in the semiconductor layers using an isotropic doping process through the bit line holes, depositing conductor material to fill the bit line holes, removing the sacrificial layers, depositing a gate dielectric layer between the semiconductor layers, and depositing gate material onto the gate dielectric layer.

### CLAIM TO PRIORITY

This application is a continuation-in-part (CIP) of U.S. patent application having application Ser. No. 18/311,212 filed on May 2, 2023, and entitled “3D Memory Cells and Array Architectures and Processes.”

This application claims the benefit of priority under 35 U.S.C. 119(e) based upon U.S. Provisional patent application having Application No. 63/544,018 filed on Oct. 13, 2023, and entitled “3D Cell and Array Structures and Processes,” and U.S. Provisional patent application having Application No. 63/544,326 filed on Oct. 16, 2023, and entitled “3D Cell and Array Structures and Processes,” and U.S. Provisional patent application having Application No. 63/609,879 filed on Dec. 14, 2023, and entitled “3D Cell and Array Structures and Processes,” all of which are hereby incorporated herein by reference in their entireties.

The application Ser. No. 18/311,212 is a continuation-in-part (CIP) of U.S. patent application having application Ser. No. 17/937,432 filed on Sep. 30, 2022, and entitled “3D Memory Cells and Array Architectures.”

The application Ser. No. 18/311,212 claims the benefit of priority under 35 U.S.C. 119(e) based upon U.S. Provisional patent application having Application No. 63/398,807 filed on Aug. 17, 2022, and entitled “Memory Cell and Array Architectures and Operation Conditions,” and U.S. Provisional patent application having Application No. 63/406,255 filed on Sep. 14, 2022, and entitled “3D Cell and Array Structures,” and U.S. Provisional patent application having Application No. 63/413,493 filed on Oct. 5, 2022, and entitled “3D Cell and Array Structures,” and U.S. Provisional patent application having Application No. 63/418,698 filed on Oct. 24, 2022, and entitled “3D Cell and Array Structures,” and U.S. Provisional patent application having Application No. 63/445,670 filed on Feb. 14, 2023, and entitled “3D Cell and Array Structures,” and U.S. Provisional patent application having Application No. 63/445,672 filed on Feb. 14, 2023, and entitled “3D Cell and Array Structures,” and U.S. Provisional patent application having Application No. 63/449,938 filed on Mar. 3, 2023, and entitled “Novel 3D DRAM Cell, Array and Technology,” and U.S. Provisional patent application having Application No. 63/458,059 filed on Apr. 7, 2023, and entitled “3D Cell and Array Structures and Processes,” and U.S. Provisional patent application having Application No. 63/460,289 filed on Apr. 18, 2023 and entitled “3D Cell and Array Structures and Processes,” all of which are hereby incorporated herein by reference in their entireties.

The application Ser. No. 17/937,432 claims the benefit of priority under 35 U.S.C. 119(e) based upon U.S. Provisional patent application having Application No. 63/398,807 filed on Aug. 17, 2022, and entitled “Memory Cell and Array Architectures and Operation Conditions,” and U.S. Provisional patent application having Application No. 63/295,874 filed on Jan. 1, 2022, and entitled “Alpha-RAM (a-RAM) or Alpha-DRAM (a-DRAM) Technology,” and U.S. Provisional patent application having Application No. 63/291,380 filed on Dec. 18, 2021 and entitled “3D DRAM-replacement Technologies,” and U.S. Provisional patent application having Application No. 63/254,841, filed on Oct. 12, 2021 and entitled “3D DRAM-replacement Technologies,” and U.S. Provisional patent application having Application No. 63/251,583 filed on Oct. 1, 2021 and entitled “3D DRAM-replacement Technologies,” all of which are hereby incorporated herein by reference in their entireties.

### CROSS REFERENCE TO RELATED APPLICATIONS

This application is related to the following co-pending application having Attorney Docket No. SIONS-PT9-CIP1 filed on May 2, 2023, and entitled “3D MEMORY CELLS AND ARRAY ARCHITECTURES.”

### FIELD OF THE INVENTION

The exemplary embodiments of the present invention relate generally to the field of memory, and more specifically to memory cells and array structures and associated processes.

### BACKGROUND OF THE INVENTION

With the increasing complexity and density of electronic circuits, memory size, complexity, and cost are important considerations. One approach to increase memory capacity is to use three-dimensional (3D) array structure. The 3D array structure has been successfully used in NAND flash memory today. However, for dynamic random-access memory (DRAM), due to its special one-transistor-one-capacitor (1T1C) cell structure, a cost-effective 3D array structure has not been realized.

### SUMMARY

In various exemplary embodiments, three-dimensional (3D) memory cells, array structures, and associated processes are disclosed. In one embodiment, a novel 3D array structure using floating-body cells to implement DRAM is disclosed. The array structure is formed using a deep trench process similar to 3D NAND flash memory. Therefore, ultra-high-density DRAM can be realized. In one embodiment, 3D NOR-type memory cells and array structures are provided. The disclosed memory cells and array structures are applicable to many technologies. For example, the inventive memory cells and array structures are applicable to dynamic random-access memory (DRAM), floating-body cell (FBC) memory, NOR-type flash memory, and thyristors.

In an exemplary embodiment, a memory cell structure is provided that includes a first semiconductor material, a floating body semiconductor material having an internal side surface that surrounds and connects to the first semiconductor material, and a second semiconductor material having an internal side surface that surrounds and connects to the floating body semiconductor material. The memory cell structure also includes a first dielectric layer connected to a top surface of the floating body material, a second dielectric layer connected to a bottom surface of the floating body material, a front gate connected to the first dielectric layer, and a back gate connected to the second dielectric layer.

In an exemplary embodiment, a three-dimensional (3D) memory array is provided that comprises a plurality of memory cells separated by a dielectric layer to form a stack of memory cells. Each memory cell in the stack of memory cells comprises a bit line formed from one of a first semiconductor material and a first conductor material, a floating body semiconductor material having an internal side surface that surrounds and connects to the bit line, a source line formed from one of a second semiconductor material and a second conductor material having an internal side surface that surrounds and connects to the floating body semiconductor material, and a word line formed from a third conductor material that is coupled to the floating body semiconductor through the dielectric layer to form a gate of the memory cell. Additionally, the bit lines of the stack of memory cells are connected to form a vertical bit line.

In an exemplary embodiment, a memory cell structure is provided that is formed by a process of alternately depositing multiple semiconductor layers and sacrificial layers to form a stack, forming vertical bit line holes through the stack using a deep trench process, forming floating bodies in the semiconductor layers using an isotropic doping process through the bit line holes, depositing conductor material to fill the bit line holes, removing the sacrificial layers, depositing a gate dielectric layer between the semiconductor layers, and depositing gate material onto the gate dielectric layer.

Additional features and benefits of the exemplary embodiments of the present invention will become apparent from the detailed description, figures and claims set forth below.

### BRIEF DESCRIPTION OF THE DRAWINGS

The exemplary embodiments of the present invention will be understood more fully from the detailed description given below and from the accompanying drawings of various embodiments of the invention, which, however, should not be taken to limit the invention to the specific embodiments, but are for explanation and understanding only.

FIG. 1A show an embodiment of a cell structure for a three-dimensional (3D) NOR-type array constructed according to the invention.

FIG. 1B shows an embodiment of an inner cell structure of the cell shown in FIG. 1A.

FIG. 1C shows another embodiment of a cell structure constructed according to the invention.

FIG. 1D shows the cell structure of FIG. 1C with portions of the cell removed.

FIG. 1E shows another embodiment of a cell structure constructed according to the invention.

FIG. 1F shows the inner cell structure of the cell shown in FIG. 1E with portions of the cell removed.

FIG. 1G shows another embodiment of a cell structure constructed according to the invention.

FIG. 1H shows the inner cell structure of the cell shown in FIG. 1G with portions of the cell removed.

FIG. 1I shows another embodiment of a cell structure constructed according to the invention.

FIG. 1J shows the inner cell structure of the cell shown in FIG. 1I with portions of the cell removed.

FIG. 1K shows another embodiment of a cell structure constructed using a junction-less thin-film transistor according to the invention.

FIG. 1L shows an embodiment of a cross-section view of the cell structure shown in FIG. 1K taken along the cross-section indicator A-A′.

FIG. 1M shows another embodiment of the cell structure using a junction-less thin-film transistor according to the invention.

FIG. 1N shows a cross-section view of the cell structure shown in FIG. 1M taken along cross-section indicator A-A′.

FIG. 1O shows another embodiment of the cell structure using a junction-less thin-film transistor according to the invention.

FIG. 1P shows a cross-section view of the cell structure shown in FIG. 1O taken along cross-section indicator A-A′.

FIG. 1Q shows an exemplary embodiment of a three-dimensional (3D) NOR-type memory cell structure using a floating body cell (FBC) configuration in accordance with the invention.

FIG. 1R shows the cell structure shown in FIG. 1Q with a front gate and a gate dielectric layer removed.

FIG. 1S shows a cell formed using a PMOS transistor.

FIG. 1T shows an embodiment of an array structure based on the cell structure shown in FIG. 1Q.

FIG. 1U shows another embodiment of an array structure according to the invention.

FIG. 1V shows an equivalent circuit diagram for the array structure shown in FIG. 1T.

FIG. 1W shows another embodiment of an equivalent circuit diagram of the array structure shown in FIG. 1T.

FIG. 2A show another embodiment of a cell structure for a 3D NOR-type flash memory constructed according to the invention.

FIG. 2B shows the inner cell structure of the cell shown in FIG. 2A with portions of the cell removed.

FIG. 2C show another embodiment of a cell structure for 3D non-volatile random-access memory constructed according to the invention.

FIG. 2D shows the inner cell structure of the embodiment shown in FIG. 2C with portions of the cell removed.

FIGS. 3A-C show embodiments of a 3D array structure constructed according to the invention.

FIGS. 4A-I show embodiments of brief process steps to form a 3D array comprising the cell structure shown in FIG. 1A in accordance with the invention.

FIG. 4J shows a summary of process conditions and materials for use with the process steps described and shown in FIGS. 4A-I.

FIGS. 5A-C show embodiments of brief process steps to form an array using the cell structure shown in FIG. 1E according to the invention.

FIGS. 6A-F show embodiments of brief process steps to form an array using the cell structure shown in FIG. 1I according to the invention.

FIGS. 7A-D show embodiments of brief process steps to form an array comprising the cell structure shown in FIG. 1I according to the invention.

FIGS. 8A-E show another embodiment of brief process steps to form an array comprising the cell structure shown in FIG. 1G according to the invention.

FIGS. 9A-C shows another embodiment of brief process steps to form the cell structure shown in FIGS. 1E-F according to the invention.

FIGS. 10A-E show another embodiment of brief process steps that are performed to form an array comprising the cell structure shown in FIG. 1K according to the invention.

FIGS. 11A-D show another embodiment of brief process steps configured to form an array comprising the cell structure shown in FIG. 1M according to the invention.

FIGS. 12A-E show another embodiment of brief process steps configured to form an array comprising the cell structure shown in FIG. 1O according to the invention.

### DETAILED DESCRIPTION

Those of ordinary skilled in the art will realize that the following detailed description is illustrative only and is not intended to be in any way limiting. Other embodiments of the present invention will readily suggest themselves to skilled persons having the benefit of this disclosure. Reference will now be made in detail to implementations of the exemplary embodiments of the present invention as illustrated in the accompanying drawings. The same reference indicators or numbers will be used throughout the drawings and the following detailed description to refer to the same or like parts.

In various exemplary embodiments, three-dimensional (3D) memory cells, array structures, and associated processes are disclosed. For example, 3D NOR-type cells and array structures and processes are disclosed. The various embodiments of the invention can be applied to many technologies. For example, aspects of the invention can be applied to dynamic random-access memory (DRAM) using floating-body cells (FBC), NOR-type flash memory, Ferroelectric random-access memory (FRAM), resistive random-access memory (RRAM), phase change memory (PCM), magneto-resistive random-access memory (MRAM), and memory elements called ‘synapses’ in in-memory computing or neural network arrays for artificial intelligence (AI) applications. In addition, embodiments of the invention are applicable to other memory applications not listed.

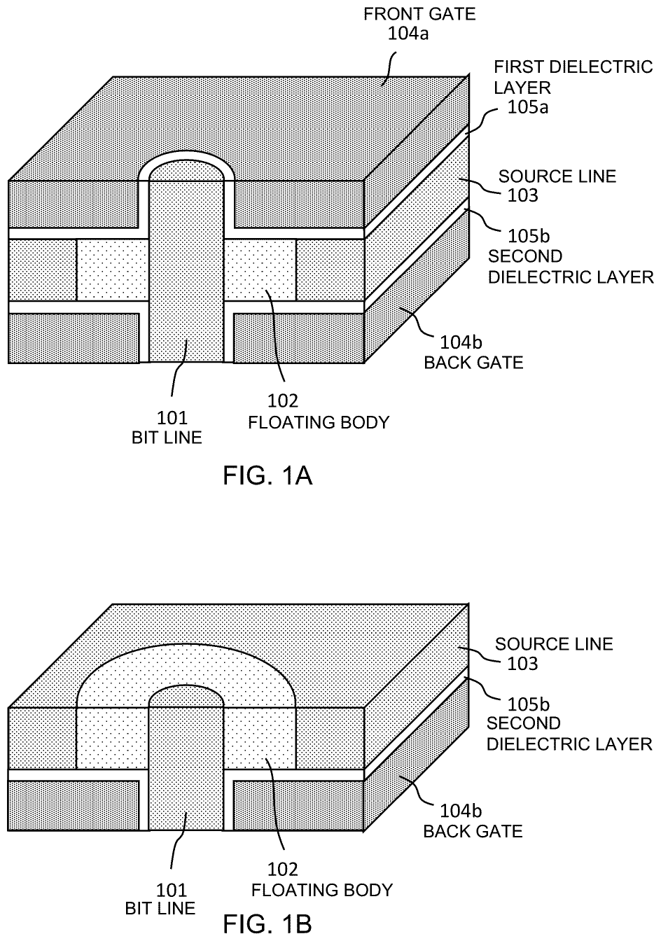

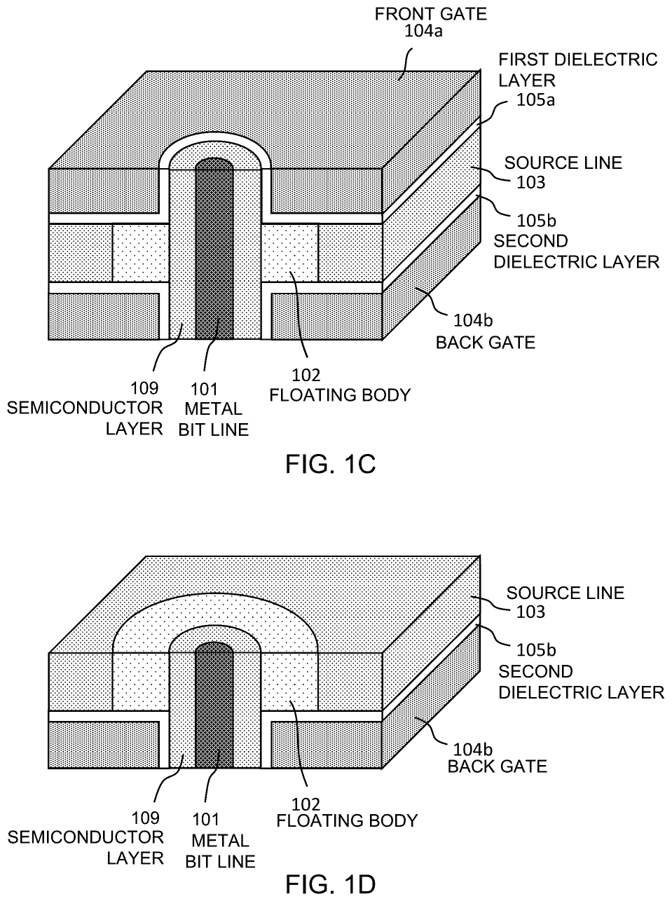

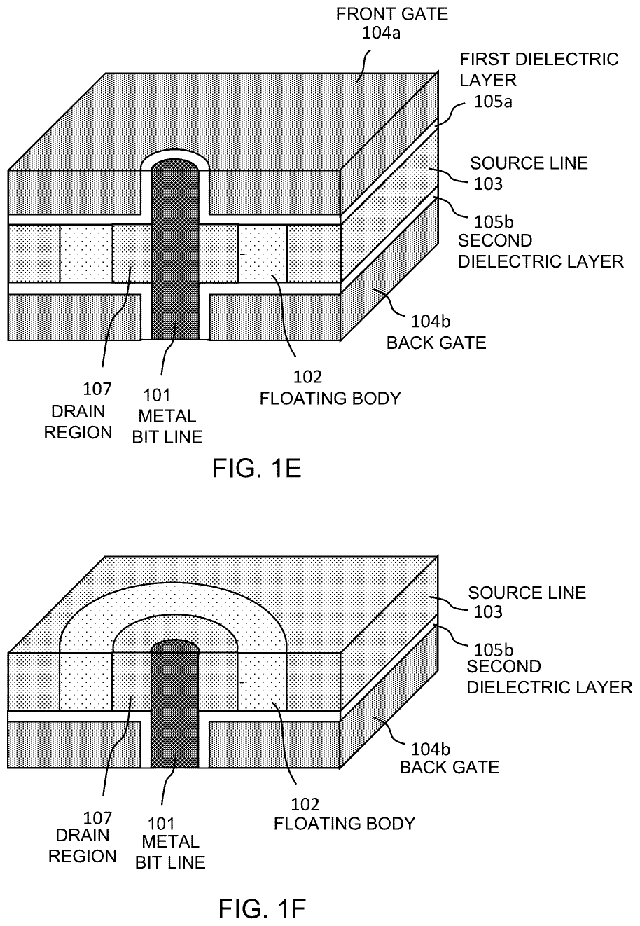

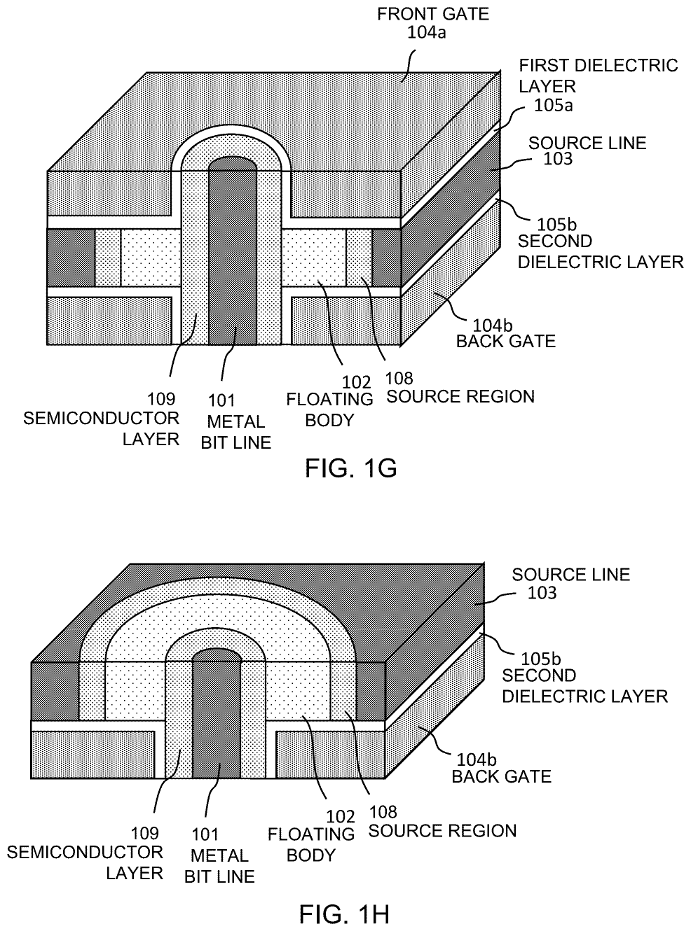

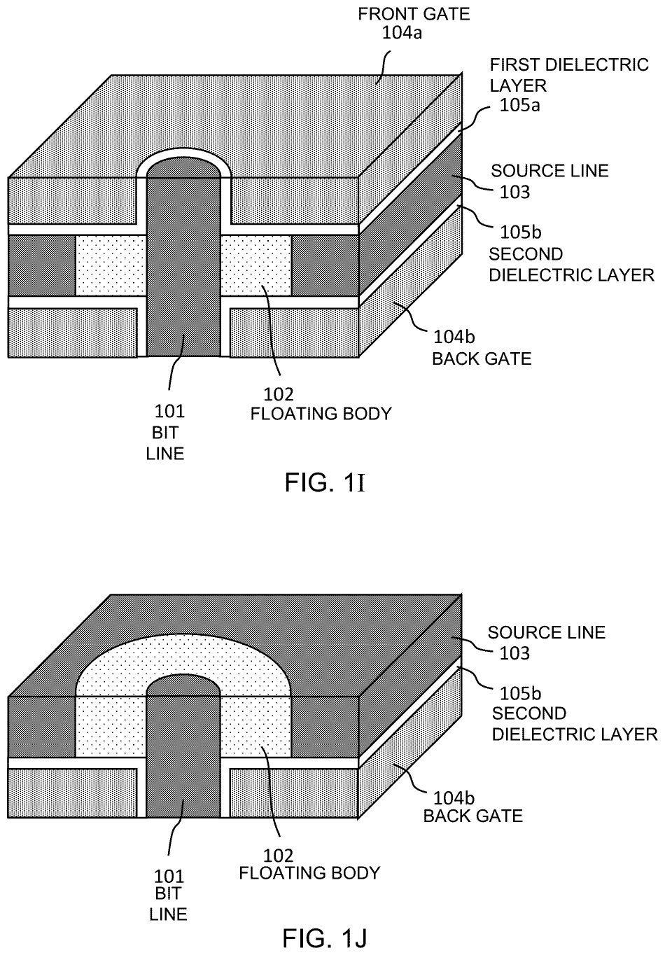

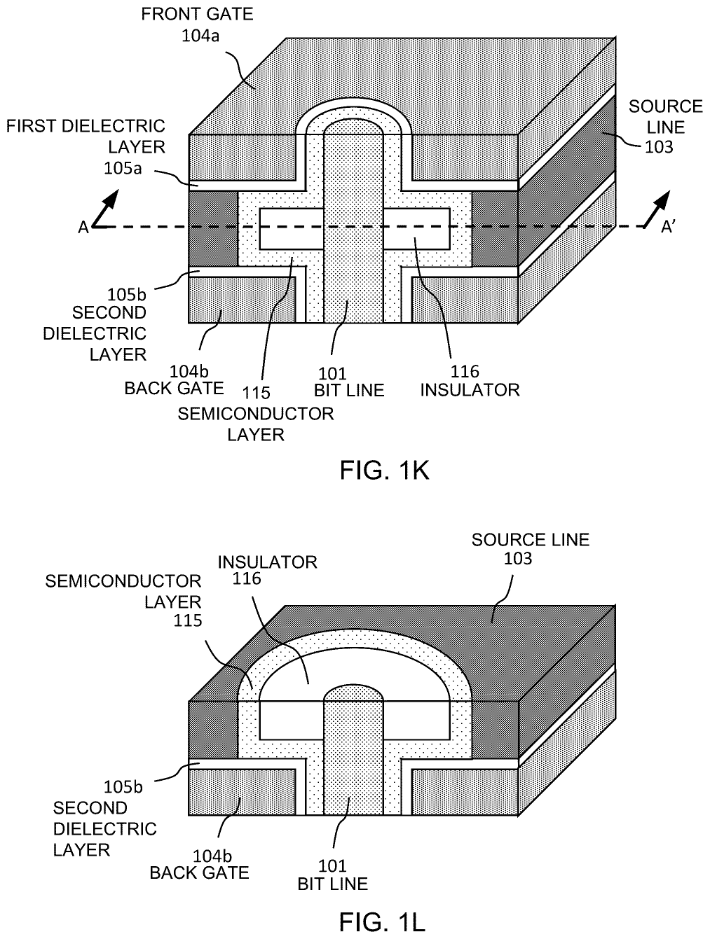

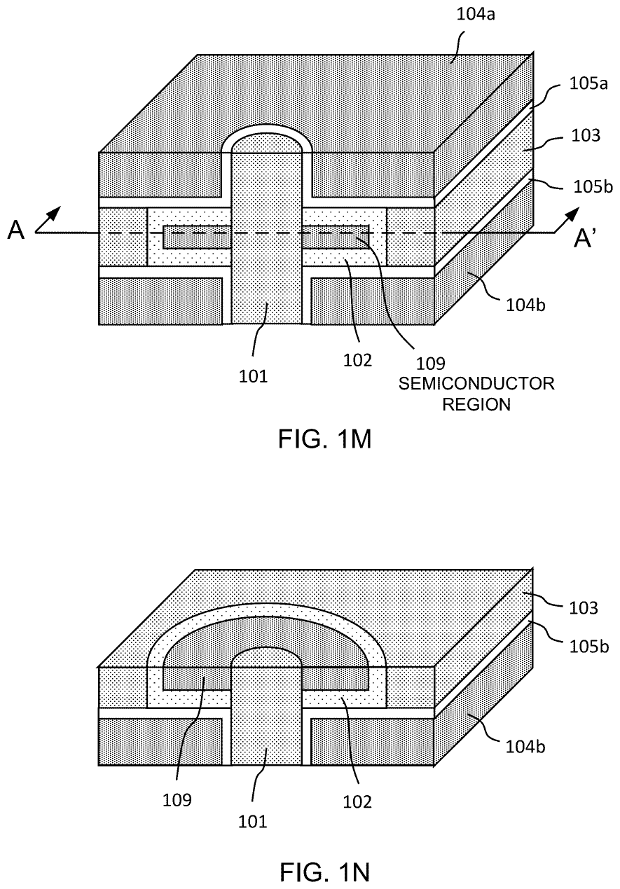

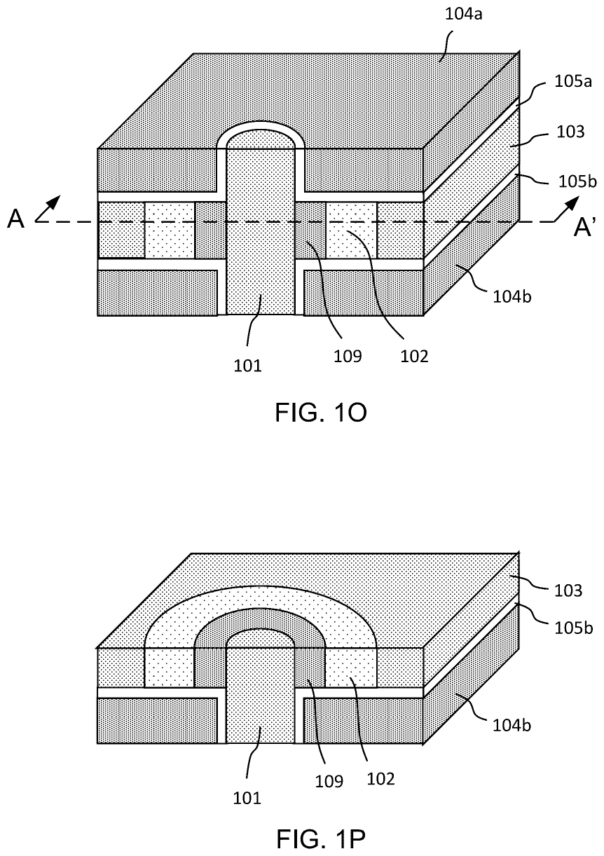

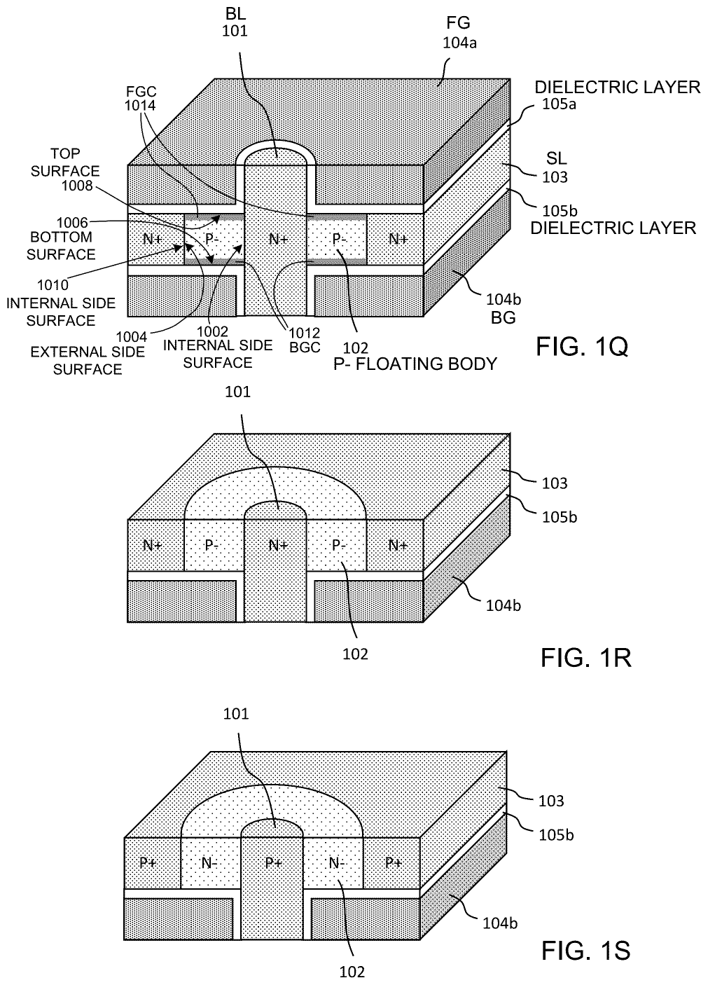

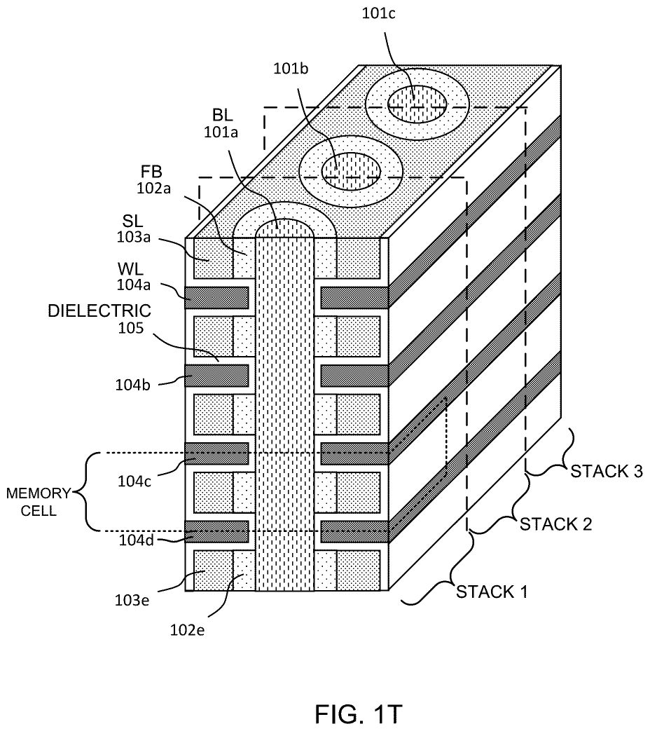

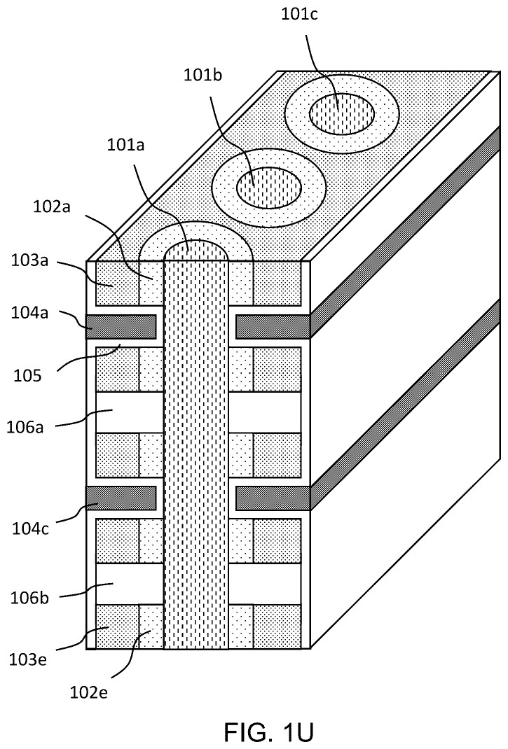

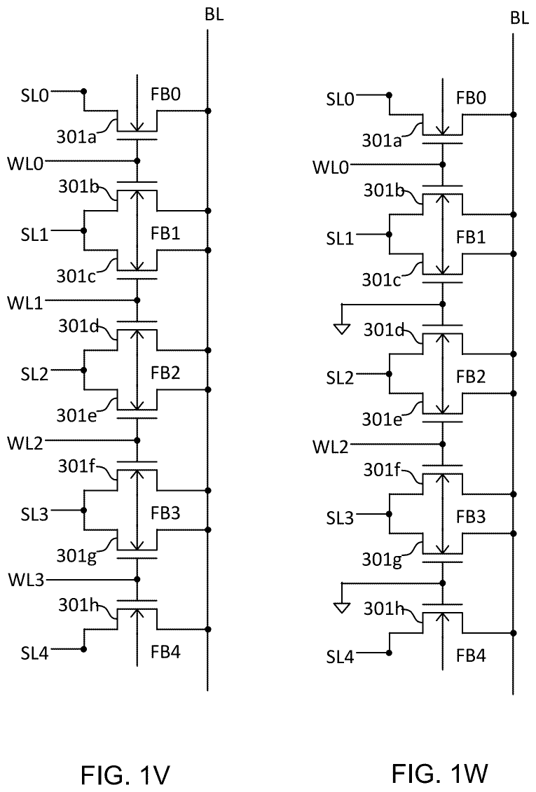

FIG. 1A show an embodiment of a cell structure for a three-dimensional (3D) NOR-type array constructed according to the invention. The cell structure shown in FIG. 1A comprises a semiconductor layer that forms a vertical bit line (BL) 101 that comprises silicon or polysilicon, a floating body 102 formed of silicon or polysilicon and a horizontal source line (SL) 103 formed of silicon or polysilicon. The cell also comprises a front gate 104a, a back gate 104b, a first gate dielectric layer 105a, and a second gate dielectric layer 105b. In one embodiment, the gates 104a and 104b are formed of conductor material, such as metal or heavily doped polysilicon. The front gate 104a and back gate 104b can be connected to horizontal word lines (WL).

The cell can be formed as either an NMOS or PMOS transistor. For an NMOS cell embodiment, the bit line 101 and the source line 103 have N+ type of doping and the floating body 102 has P− type of doping. For the PMOS cell embodiment, the bit line 101 and the source line 103 have P+ type of doping and the floating body 102 has N− type of doping.

FIG. 1B shows an embodiment of the inner cell structure of the cell shown in FIG. 1A with the front gate 104a, the gate dielectric layer 105a, and a portion of the BL 101 removed. Although the embodiments shows that the shapes of the bit line 101 and floating body 102 are circular, in other embodiments, the bit line 101 and the floating body 102 can have any suitable shapes, such as square, rectangular, triangular, hexagon, etc. These variations are within the scope of the embodiments.

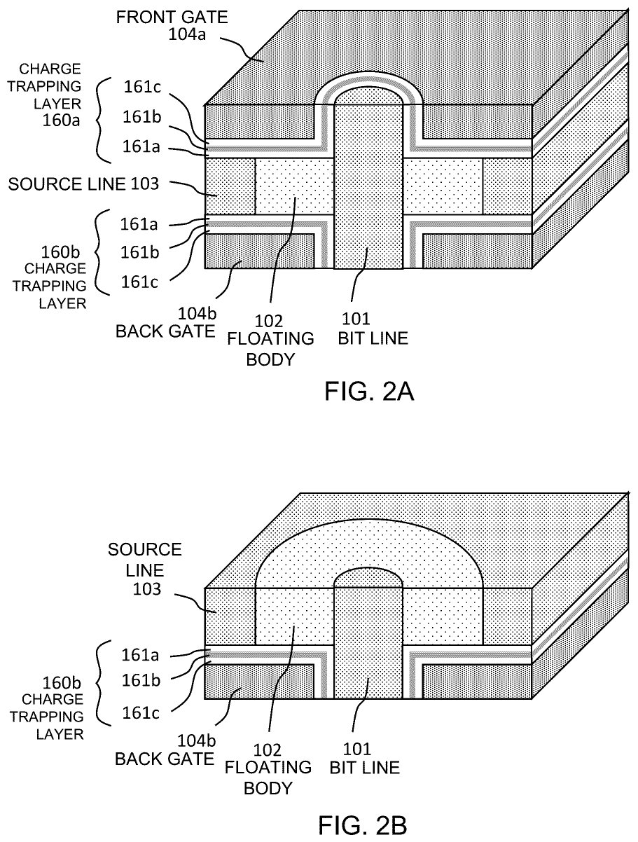

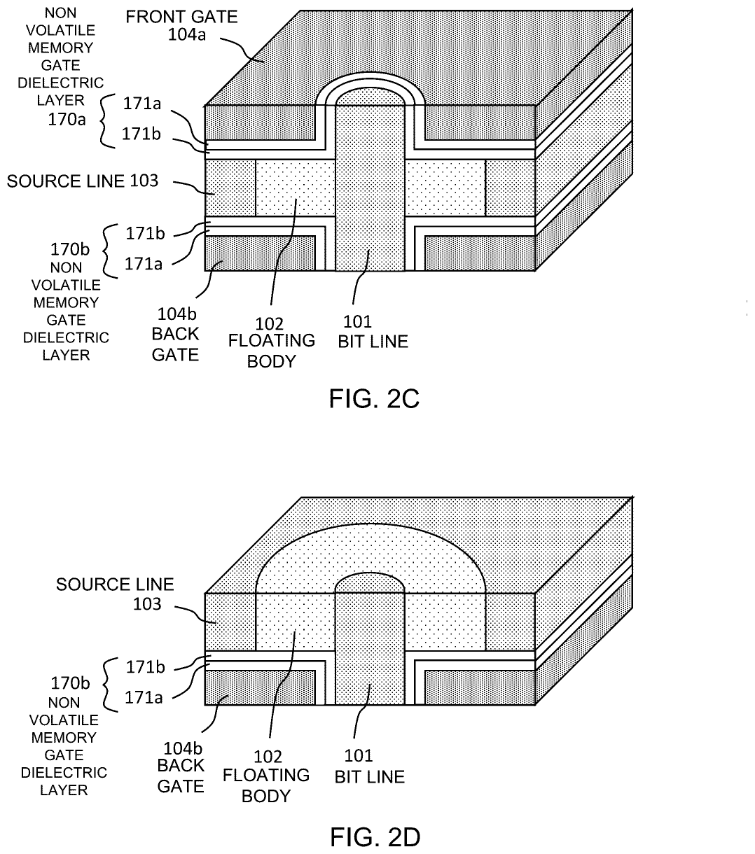

Depending on the cell types and technologies, the gate dielectric layers 105a and 105b can be formed of a variety of different materials and structures. For example, in one embodiment, the cell may be formed as a floating-body cell for DRAM application. For this embodiment, the gate dielectric layers 105a and 105b are thin gate oxide layers or high-K material layers, such as hafnium oxide (HfO2). In another embodiment, the gate dielectric layers 105a and 105b are formed from other suitable materials to form NOR-type flash memory, ferroelectric random-access memory (FRAM), resistive random-access memory (RRAM), phase-change memory (PCM), magneto-resistive random-access memory (MRAM), and others. as shown in FIG. 2A-D.

FIG. 1C shows another embodiment of a cell structure constructed according to the invention. This embodiment is similar to the embodiment in FIG. 1A except that a metal vertical bit line 101 is formed of a metal core in the center of the semiconductor layer 109 to reduce the bit line resistance.

FIG. 1D shows the cell structure of FIG. 1C with the front gate 104a and gate dielectric layer 105a and a portion of the metal BL 101 and the semiconductor layer 109 removed.

FIG. 1E shows another embodiment of a cell structure constructed according to the invention. This embodiment is similar to the embodiments shown in FIGS. 1C-D except that a drain region 107 is formed around the side of the metal bit line 101 as shown. In an embodiment, the drain region 107 is formed of silicon or polysilicon with the opposite type of heavy doping as the doping of the floating body 102. For example, the ‘opposite type of doping’ means that P-type (positive) doping is the opposite of N-type (negative) doping. For example, if the floating body 102 comprises P-type doping, the drain region 107 comprises N-type doping, which is the opposite type of doping. If the floating body 102 comprises N-type doping, the drain region 107 comprises P-type doping, which is the opposite type of doping. The terms ‘heavy doping’ and ‘light doping’ are relative terms that describe the amount of doping. When a semiconductor is doped with excess electrons or holes, it is called a heavily doped semiconductor, indicated by N+ or P+, respectively. When a semiconductor is doped with a small amount of electrons or holes, it is called a lightly doped semiconductor, indicated by N− or P−, respectively. As shown in FIG. 1E, the vertical bit line hole is filled with metal to form the metal bit line 101 to reduce the bit line resistance.

FIG. 1F shows the inner cell structure of the cell shown in FIG. 1E with the front gate 104a, the gate dielectric layer 105a, and a portion of the metal bit line 101 removed.

FIG. 1G shows another embodiment of a cell structure constructed according to the invention. This embodiment is similar to the embodiments shown in FIGS. 1C-D except that the source line 103 is formed of conductor material, such as metal to reduce the source line resistance. A source region 108 comprising semiconductor material, such as silicon or polysilicon, is formed between the metal source line 103 and the floating body 102. The source region 108 has the opposite type of heavy doping from the doping of the floating body 102.

FIG. 1H shows the inner cell structure of the cell shown in FIG. 1G with the front gate 104a and the gate dielectric layer 105a, and a portion of the metal BL 101 and the semiconductor layer 109 removed.

FIG. 1I shows another embodiment of a cell structure constructed according to the invention. This embodiment is similar to FIGS. 1A-B except that the bit line 101 and the source line 103 are formed of metal. A floating body 102 is formed of semiconductor material, such as silicon or polysilicon. In one embodiment, the floating body 102 has N+ or P+ type of heavy doping. This forms a junction-less cell transistor. In another embodiment, the floating body 102 has N− or P− type of light doping. This forms a Schottky-junction cell transistor.

FIG. 1J shows the inner cell structure of the cell shown in FIG. 1I with the front gate 104a, the gate dielectric layer 105a, and a portion of the BL 101 removed.

FIG. 1K shows another embodiment of a cell structure constructed using a junction-less thin-film transistor according to the invention. This embodiment is similar to the embodiments shown in FIGS. 1A-B except that a semiconductor layer 115 comprising silicon, polysilicon, germanium (Ge), indium gallium zinc oxide (IGZO), tungsten-doped indium oxide semiconductor, or any other suitable semiconductor material surrounds the BL 101 and an insulator 116 that comprises oxide or nitride. In one embodiment, the semiconductor layer 115 has N-type or P-type of heavy doping to form the channel of the cell transistor. In one embodiment, the bit line 101 and the source line 103 are formed of conductor material, such as metal or heavily doped polysilicon. FIG. 1K also shows a cross-section indicator A-A′.

FIG. 1L shows an embodiment of a cross-section view of the cell structure shown in FIG. 1K taken along the cross-section indicator A-A′ shown in FIG. 1K.

FIG. 1M shows another embodiment of the cell structure using a junction-less thin-film transistor according to the invention. This embodiment is similar to the embodiments shown in FIGS. 1A-B except for a semiconductor region 109. The semiconductor region 109 is formed of a different material from the floating body 102. For example, if the floating body 102 is formed of silicon or polysilicon, the semiconductor region 109 is formed of silicon germanium (SiGe), silicon carbide (SiC), or any other suitable semiconductor materials. This configuration forms a heterostructure junction between the two materials and forms a quantum well inside the semiconductor region 109 to store the electric charge, such as holes. This increases the data retention time of the cell.

FIG. 1N shows a cross-section view of the cell structure shown in FIG. 1M taken along cross-section indicator A-A′ shown in FIG. 1M.

FIG. 1O shows another embodiment of the cell structure using a junction-less thin-film transistor according to the invention. This embodiment is similar to the embodiments shown in FIGS. 1M-N except that the semiconductor region 109 is formed in a different shape. The semiconductor region 109 is formed of a different material from the floating body 102. For example, if the floating body 102 is formed of silicon or polysilicon, the semiconductor region 109 is formed of silicon germanium (SiGe), silicon carbide (SiC), or any other suitable semiconductor materials. This forms a heterostructure junction between the two materials and forms a quantum well inside the semiconductor region 109 to store the electric charge, such as holes. This increases the data retention time of the cell.

FIG. 1P shows a cross-section view of the cell structure shown in FIG. 1O taken along cross-section indicator A-A′ shown in FIG. 1O.

FIG. 1Q show an exemplary embodiment of a three-dimensional (3D) NOR-type memory cell structure using a floating body cell (FBC) configuration in accordance with the invention. For example, a 3D NOR-type array can comprise multiple layers of floating-body cell arrays to increase the memory capacity. A floating-body cell is basically a transistor with floating body. The floating body stores electric charges, such as electrons or holes to represent the data. The cell structure comprises a control gate, a drain, a source, and a floating body. In the 3D memory array, the control gate, drain, and source of the cells are connected to a word line (WL), bit line (BL), and source line (SL), respectively.

In the cell structure shown in FIG. 1Q, an N+ silicon or polysilicon forms a bit line (BL) 101 and a P− floating body 102 is used for charge storage. An N+ silicon or polysilicon forms a source line (SL) 103. The cell may be formed as a dual-gate transistor shown in FIG. 1Q or a single-gate transistor as shown in FIG. 1R. For the dual-gate transistor shown in FIG. 1Q, the cell structure comprises two control gates called a front gate 104a and a back gate 104b, respectively. Both the front gate 104a and the back gate 104b are coupled to the floating body 102 through gate dielectric layers 105a and 105b, respectively. The gate dielectric layer is an insulating layer between the gate and the body of the transistor. When a proper voltage is applied to the front gate 104a or the back gate 104b, a front gate channel (FGC) 1014 or a back gate channel (BGC) 1012 are formed in the surface of the floating body 102 under the gate dielectric layer 105a and 105b to conduct current between the bit line 101 and source line 103. In an embodiment, the front gate 104a and back gate 104b are connected to different word lines (WL).

In an embodiment, the P− floating body 102 comprises multiple surfaces as shown in FIG. 1Q. An internal side surface 1002 surrounds and connects to the BL 101. An external side surface 1004 connects to the source line 103. A top surface 1008 connects to the dielectric layer 105a, and a bottom surface 1006 connects to the dielectric layer 105b. Thus, in one embodiment, a memory cell structure is provided that includes a first semiconductor material BL 101, a floating body semiconductor material 102 having an internal side surface 1002 that surrounds and connects to the first semiconductor material BL 101, and a second semiconductor material SL 103 having an internal side surface 1010 that surrounds and connects to the floating body semiconductor material 102. The memory cell structure also includes a first dielectric layer 105a connected to a top surface 1008 of the floating body material 102, a second dielectric layer 105b connected to a bottom surface 1006 of the floating body material 102, a front gate 104a connected to the first dielectric layer 105a, and a back gate 104b connected to the second dielectric layer 105b. In various embodiments, minor modifications can be made to the disclosed structures, such as adding a lightly doped drain (LDD), halo implantation, pocket implantation, or channel implantation that are all included within the scope of the invention.

FIG. 1R shows the cell structure shown in FIG. 1Q with the front gate 104a, the gate dielectric layer 105a, and a portion of the bit line 101 removed. The P− floating body 102 forms a donut shape as shown. Although this embodiment shows that the shapes for the bit line 101 and floating body 102 are circular, it is obvious that they have any desired shape, such as square, rectangle, triangle, hexagon, etc. These variations shall remain in the scope of the invention.

In one embodiment, the cell structure comprises only one single gate, as shown in FIG. 1R. The floating body 102 is coupled to only one gate 104b as shown. An embodiment of a 3D array structure using this cell structure embodiment is shown in FIG. 1T.

The embodiment shown in FIG. 1Q uses an NMOS transistor as the cell. In another embodiment, shown in FIG. 1S, the cell is formed using a PMOS transistor. The bit line 101, floating body 102, and source line 103 are formed by P+, N−, and P+ materials, respectively.

FIG. 1T shows an embodiment of an array structure based on the cell structure shown in FIG. 1Q. The array structure comprises vertical bit lines 101a to 101c and floating bodies 102a to 102e. The array structure also comprises source lines 103a to 103e and word lines 104a to 104d. The array structure also includes dielectric layer 105 comprising a gate oxide or high-K material, such as HfOx.

In an embodiment, a three-dimensional (3D) memory array comprises a plurality of memory cells separated by a dielectric layer to form a stack of memory cells. For example, FIG. 1T shows a 3D array having three stacks of memory cells and a particular “memory cell” is identified. Each memory cell in the stack of memory cells comprises a bit line 101 formed from one of a first semiconductor material and a first conductor material, a floating body semiconductor material 102 having an internal side surface that surrounds and connects to the bit line, a source line 103 formed from one of a second semiconductor material and a second conductor material having an internal side surface that surrounds and connects to the floating body semiconductor material 102, and a word line 104 formed from a third conductor material that is coupled to the floating body semiconductor 102 through a dielectric layer 105 to form a gate of the memory cell. Additionally, the bit lines of the stack of memory cells are connected to form a vertical bit line (e.g., 101a).

FIG. 1U shows another embodiment of an array structure according to the invention. This embodiment is similar to the embodiment shown in FIG. 1T except that the cells are single-gate transistors. Also shown in FIG. 1U are insulating layers 106a and 106b that are formed from material, such as oxide.

FIG. 1V shows an equivalent circuit diagram for the array structure shown in FIG. 1T. For example, the equivalent circuit shows transistors 301a-h that are formed by the array structure shown in FIG. 1T. Referring again to the array structure in FIG. 1T, the word line structures 104a to 104d are connected to word lines WL0-WL3. The floating bodies structures 102a to 102e are the floating bodies FB0-FB4. The source line structures 103a to 103e are connected to the source lines SL0-SL4, and the bit line structure 101a is a vertical bit line (BL). In this embodiment, each floating body (e.g., FB0-FB4) is coupled to two word lines. This array requires special bias conditions for read and write operations to avoid two cells being selected at the same time.

FIG. 1W shows another embodiment of an equivalent circuit diagram of the array structure shown in FIG. 1T. This embodiment is similar to the embodiment shown in FIG. 1V except that the odd word lines, WL1, WL3, and so on, are connected to ground. This turns off the transistors 301c, 301d, 301g, and 301h. In this embodiment, each floating body is coupled to one word line only. However, the storage capacity of this embodiment is reduced to one half when compared with the embodiment shown in FIG. 1V.

FIG. 2A show another embodiment of a cell structure for a 3D NOR-type flash memory constructed according to the invention. This embodiment is similar to the embodiments shown in FIGS. 1A-B except that the gate dielectric layers 105a and 105b are replaced with charge trapping layers 160a and 160b that comprise oxide-nitride-oxide (ONO) layers. In one embodiment, the charge trapping layer 160b comprises a tunnel oxide layer 161a that is thin enough to allow electrons to tunnel through when a high electric field is applied. This changes the threshold voltage of the cells to represent the stored data. A nitride layer 161b traps electrons for data storage. A blocking oxide 161c is thick enough to prevent electrons from tunneling through to the gates 104a and 104b. In another embodiment, the blocking oxide 161c comprises a tunnel oxide layer and the tunnel oxide layer 161a comprises a blocking oxide layer. In this embodiment, during programming, electrons are injected from a selected one of the gates 104a or 104b to the nitride layer 161b.

FIG. 2B shows the inner cell structure of the cell shown in FIG. 2A with the front gate 104a, the charge trapping layer 160a, and a portion of the BL 101 removed.

Although ONO layers 161a-c shown in FIG. 2B are used as an example for the charge-trapping layers 160a and 160b, in other embodiments, the charge-trapping layers 160a and 160b comprise any suitable number of oxide layers and nitride layers. For example, in another embodiment, the charge-trapping layers 160a and 160b comprise oxide-nitride-oxide-nitride-oxide (ONONO) layers. In another embodiment, the charge-trapping layers 160a and 160b comprise only one oxide and one nitride (ON) layers. These variations are within the scope of the embodiments.

In various embodiments, the charge-trapping layers 160a and 160b are also utilized in the other cell embodiments shown in FIGS. 1A-L to replace the gate dielectric layers 105a and 105b to form different types of NOR flash memory cells.

FIG. 2C show another embodiment of a cell structure for 3D non-volatile random-access memory constructed according to the invention. This embodiment is similar to the embodiments shown in FIGS. 1A-B except that the gate dielectric layers 105a and 105b are replaced with non-volatile memory gate dielectric layers 170a and 170b. In one embodiment, the non-volatile memory gate dielectric layers 170a and 170b comprise multiple layers, such as 171a and 171b.

FIG. 2D shows the inner cell structure of the embodiment shown in FIG. 2C with the front gate 104a, the non-volatile memory gate dielectric layer 170a, and a portion of the BL 101 removed.

In one embodiment that forms a ferroelectric random-access memory (FRAM), the non-volatile memory gate dielectric layer 170b comprises a ferroelectric layer 171a, such as lead zirconate titanate (PZT) or hafnium oxide (HfO2) in orthorhombic crystal phase, or hafnium zirconium oxide (HfZrO2). The layer 171b comprises a dielectric layer, such as hafnium oxide (HfO2). When high voltages are applied to the gates 104a and 104b, the generated electric field alters the pole of the ferroelectric materials in the ferroelectric layer 171a to change the threshold voltage of the cells to represent the stored data.

In another embodiment that forms a resistive random-access memory (RRAM), the non-volatile memory gate dielectric layers 170a and 170b comprise an adjustable resistive layer 171a, such as hafnium oxide (HfOx), titanium oxide (TiOx), or tantalum oxide (TaOx), and a dielectric layer 171b, such as silicon oxide (SiO₂). In another embodiment that forms a phase-change memory (PCM), the non-volatile memory gate dielectric layers 170a and 170b are formed of multiple layers comprising at least one phase-change layer 171a, such as Germanium Antimony Tellurium alloy or chalcogenide glass, Ge2Sb2Te5 (GST), and a heater layer 171b, such as tungsten (W), titanium (Ti), or polysilicon.

In another embodiment, that forms a magneto-resistive random-access memory (MRAM), the non-volatile memory gate dielectric layers 170a and 170 comprise multiple layers including ferromagnetic material 171a and 171b, such as iron-nickle (NiFe) or iron-cobalt (CoFe) alloys, and a tunnel-barrier layer formed such as hafnium oxide (HfO₂) between the layers 171a and 171b. The materials of the non-volatile memory gate dielectric layers 170a and 170b described above are just some examples and any other suitable materials can be used for the non-volatile memory gate dielectric layers 170a and 170b within the scope of the embodiments.

The non-volatile memory gate dielectric layers 170a and 170b shown in this embodiment can be also utilized with all the other cell embodiments shown in FIG. 1A-L to replace the gate dielectric layers 105a and 105b to form various types of non-volatile random-access memory cells.

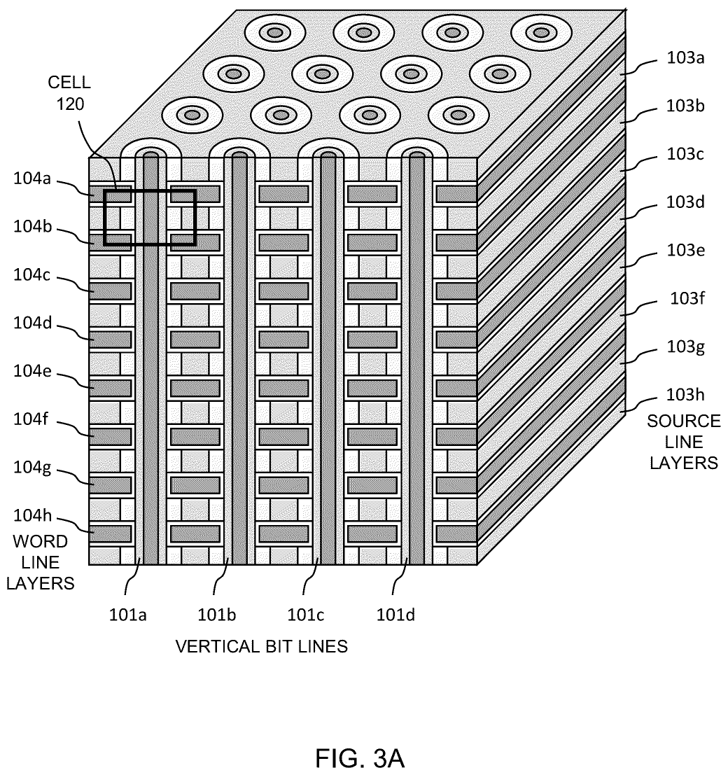

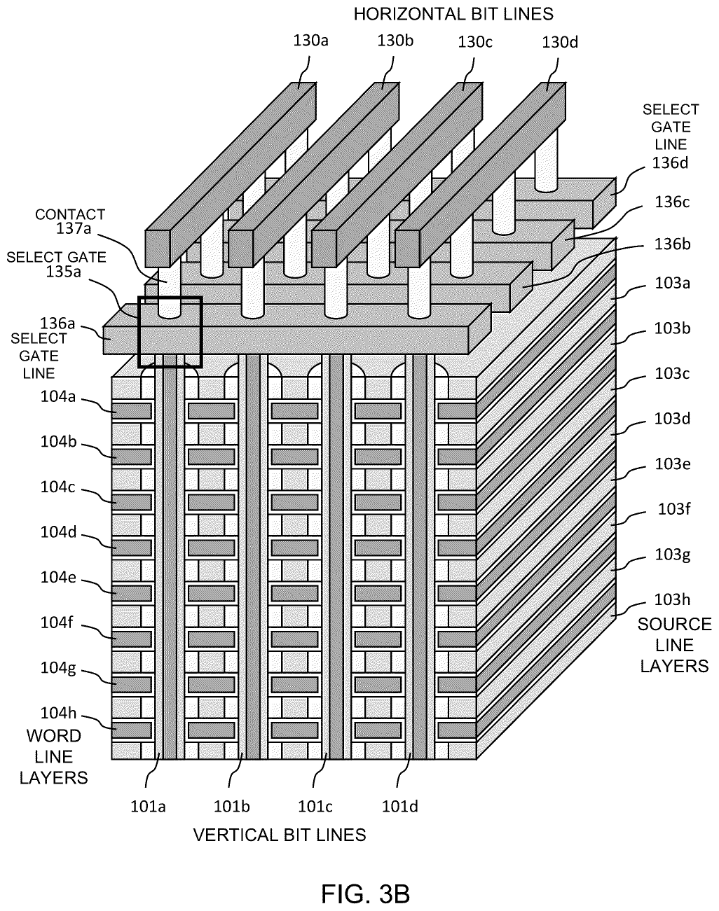

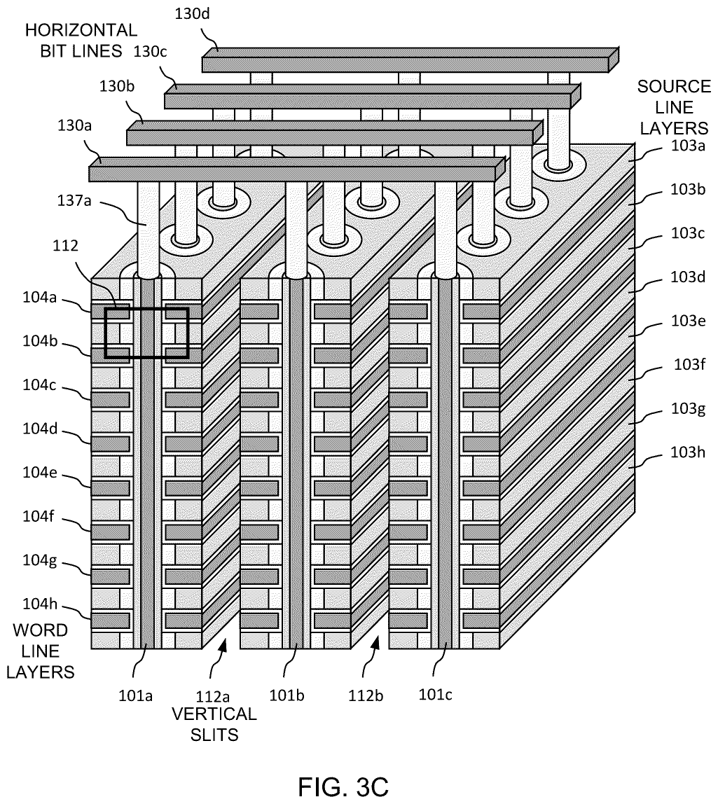

FIGS. 3A-C show embodiments of a 3D array structure constructed according to the invention. FIG. 3A shows a 3D array formed using the cell structures shown in FIGS. 1C-D. However, in other embodiments, the 3D array structure is formed utilizing any other cell structures shown in FIGS. 1A-2D. The 3D array comprises multiple layers of cells stacked vertically. The cells are connected to vertical bit lines, such as vertical bit lines 101a to 101d. The 3D array comprises multiple word line layers 104a to 104h that are connected to the gates of the cells. The 3D array also comprises multiple source line layers 103a to 103h. Each intersection of one of the vertical bit lines 101a to 101d and one of the source lines 103a to 103h form a cell, such as the cell 120.

FIG. 3B shows an embodiment of a bit line connections to the 3D array structure shown in FIG. 3A that are constructed according to the invention. The vertical bit lines 101a to 101d are connected to horizontal bit lines 130a to 130d through select gates, such as select gate 135a and contacts, such as contact 137a. The horizontal bit lines 130a to 130d are formed of conductor material, such as metal or heavily doped polysilicon. The select gates, such as select gate 135a, are formed of vertical-channel transistors. Select gate lines 136a to 136d are connected to control gates of the vertical channel select gates, such as select gate 135a.

The word line layers 104a to 104h and source line layers 103a to 103h are connected to the word line decoders (not shown) and source line voltage generators (not shown), respectively, by forming staircase structures for the word lines and the source lines at the edge of the array as structured in a conventional 3D NAND flash memory.

FIG. 3C shows another embodiment of the 3D array structure according to the invention. The array is divided into multiple stacks by vertical slits 112a and 112b. Because each stack is connected to different word lines such as 104 to 104h, the vertical bit lines such as 101a to 101c may be connected to the horizontal bit lines 130a to 130d without the vertical select gates such as 135a shown in FIG. 3B.

The 3D array structure can be utilized in various 3D NOR-type memory applications, such as dynamic random-access memory (DRAM) using floating-body cell (FBC), NOR-type flash memory, ferroelectric random-access memory (FRAM), resistive random-access memory (RRAM), phase change memory (PCM), and magneto-resistive random-access memory (MRAM).

Moreover, the 3D array structure can be applied to in-memory computing and 3D neural network arrays for artificial intelligence (AI) applications. For these applications, the vertical bit line 101a to 101d, word line layers 104a to 104h, and the source line layers 103a to 103h are connected to input neuron circuits and output neuron circuits. Besides these applications, the novel 3D cell and array structures constructed according to the invention are suitable for use in any other applications.

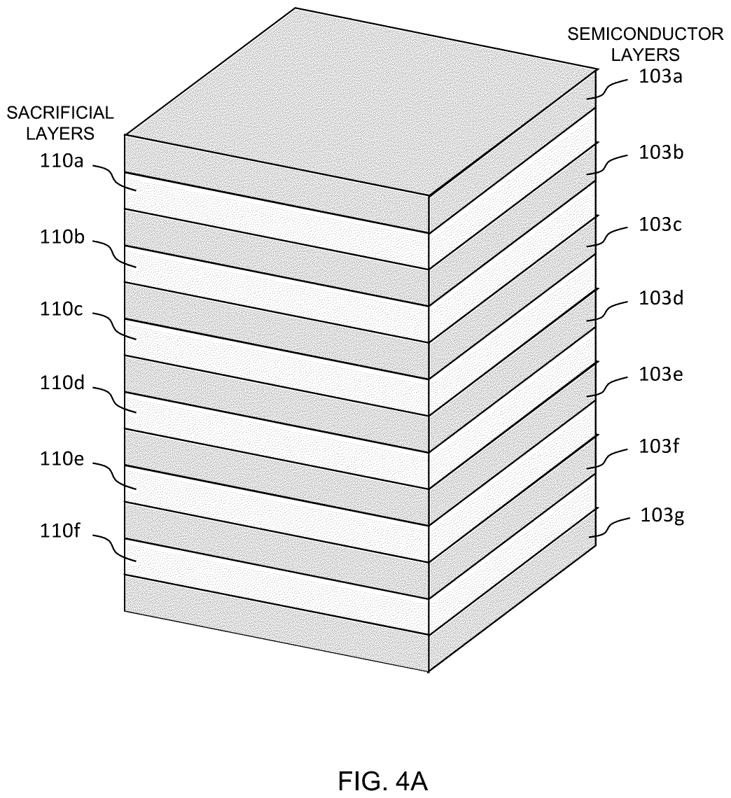

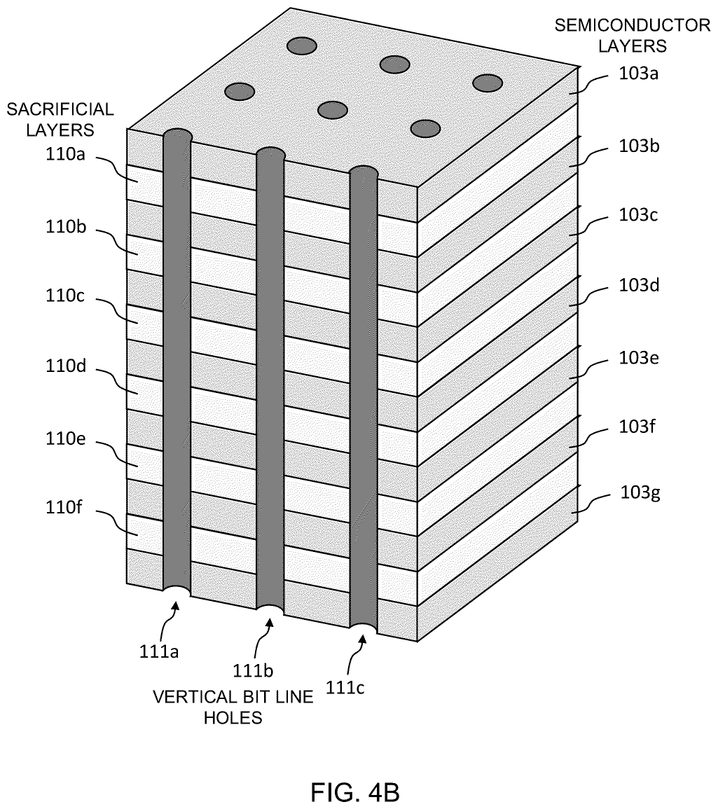

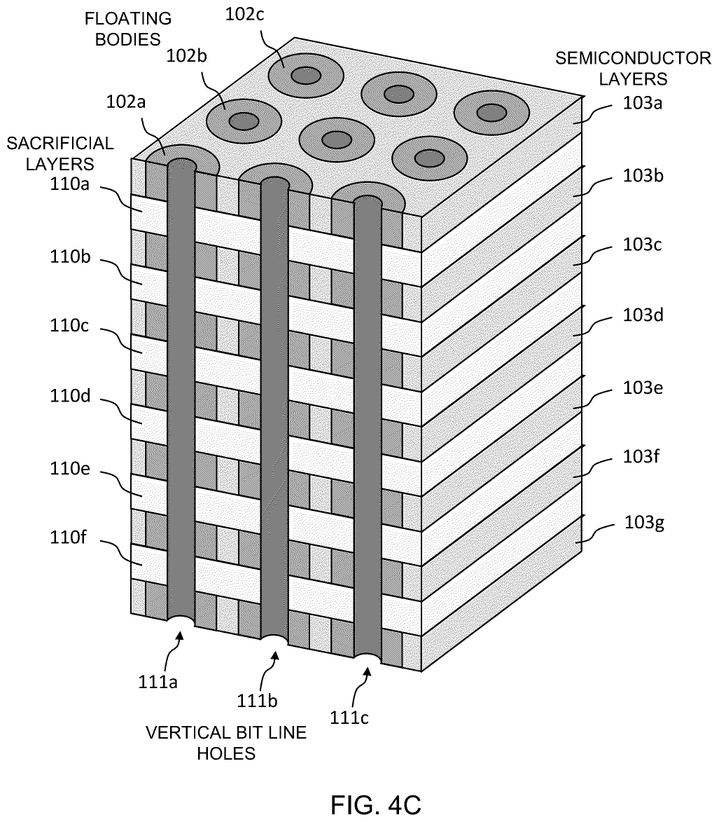

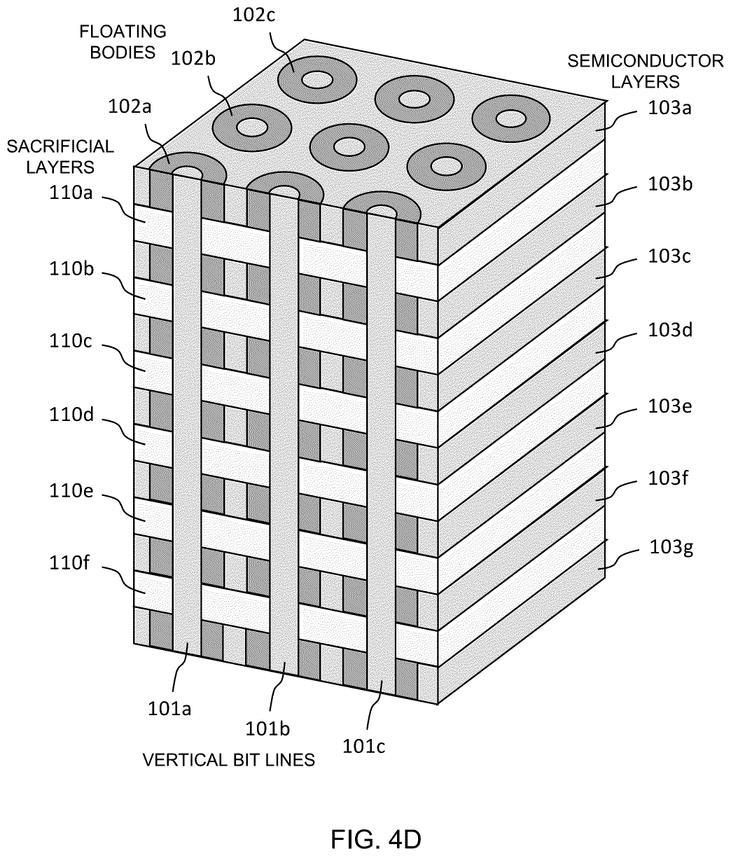

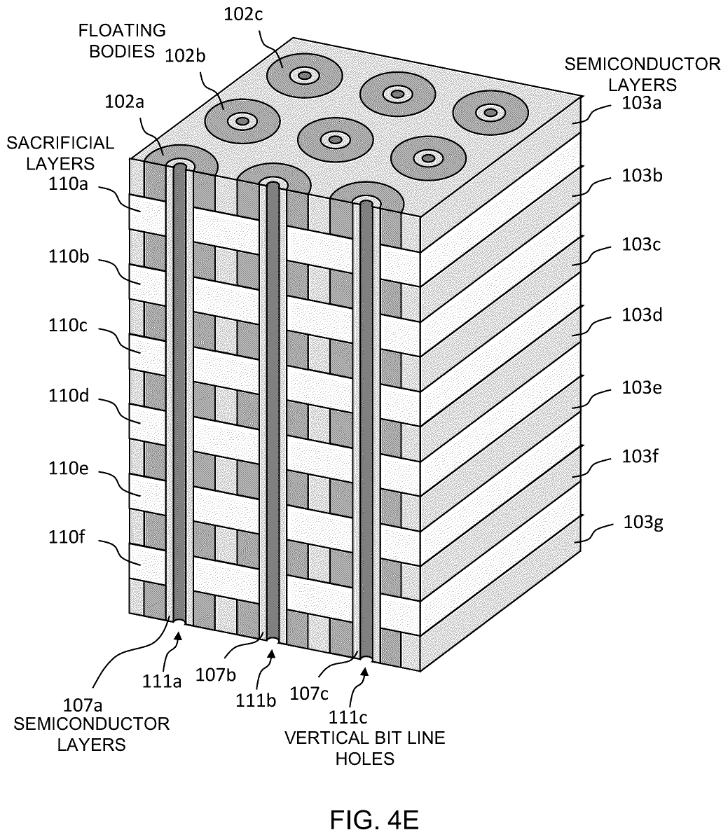

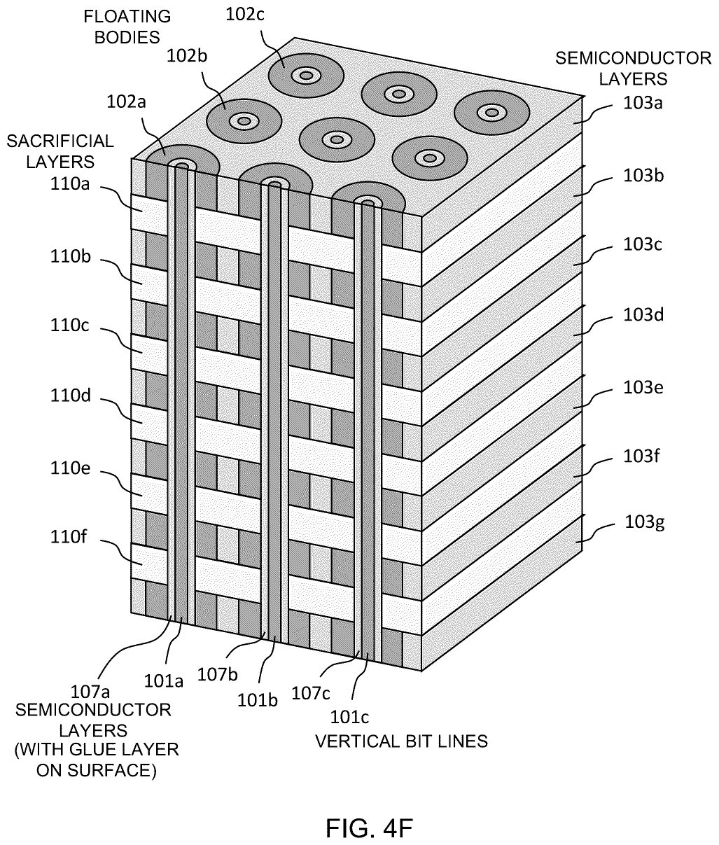

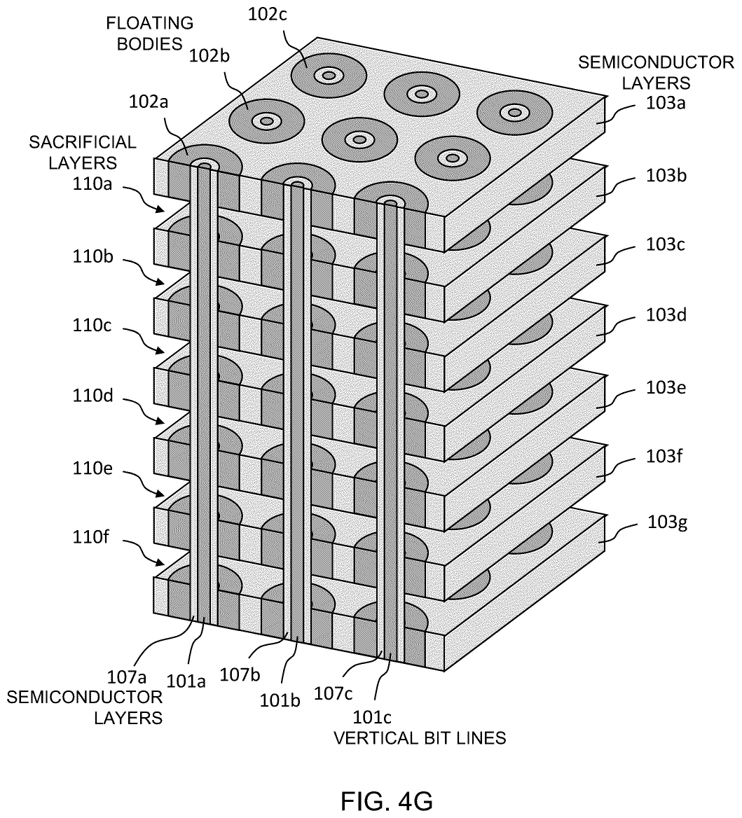

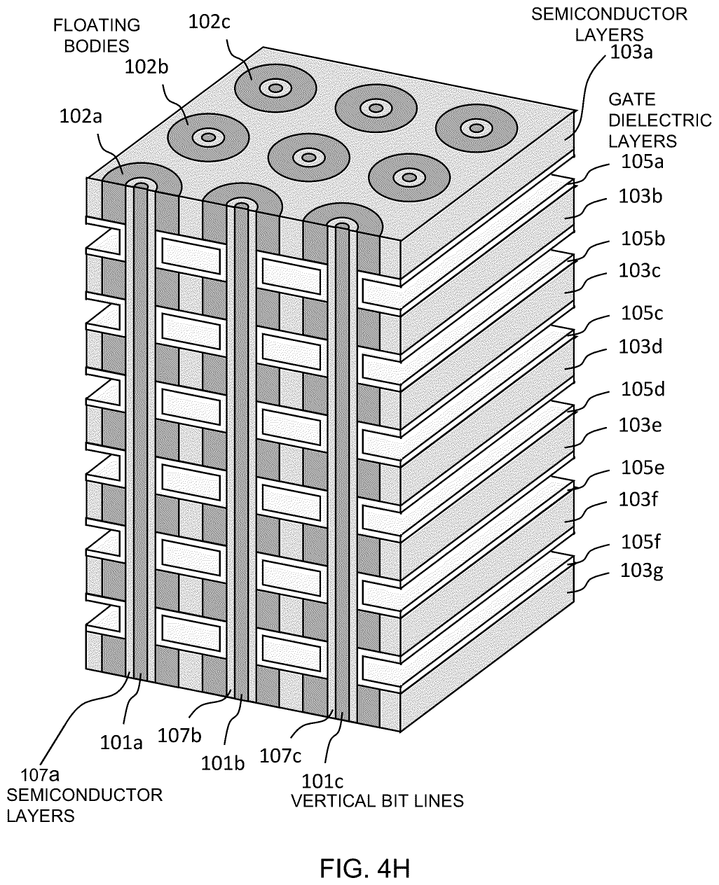

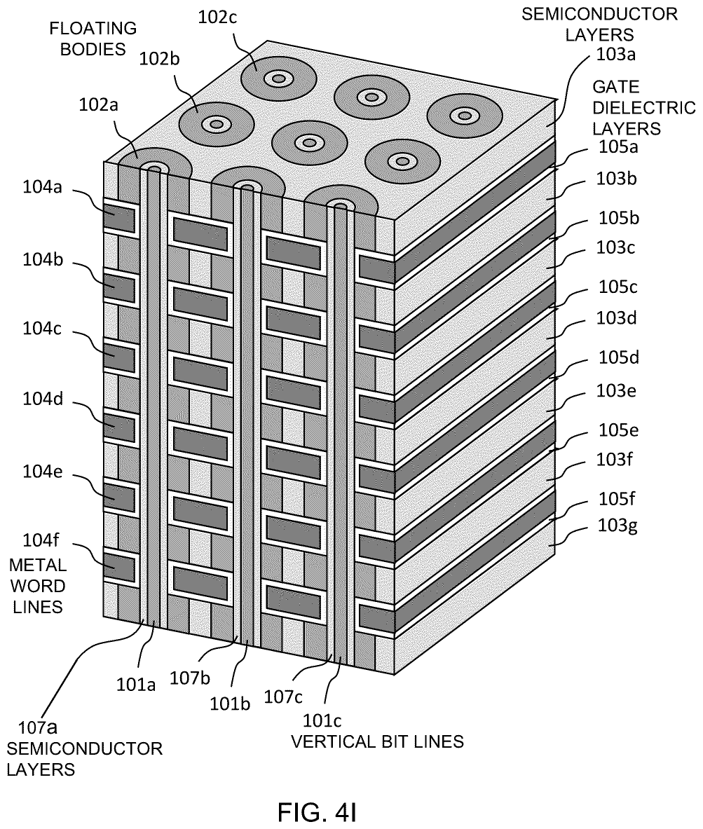

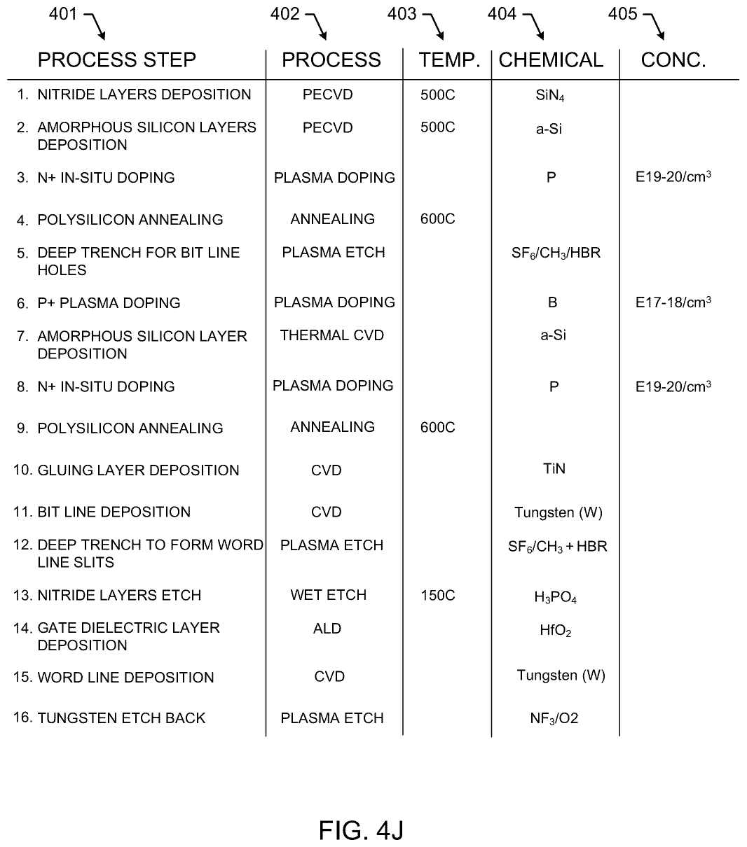

FIGS. 4A-I show embodiments of brief process steps to form a 3D array comprising the cell structure shown in FIG. 1A in accordance with the invention.

FIG. 4A shows how multiple semiconductor layers 103a to 103g and multiple sacrificial layers 110a to 110f are alternately deposited to form a stack. In one embodiment, the semiconductor layers 103a to 103g comprise silicon or polysilicon layers. The sacrificial layers 110a to 110f comprise oxide or nitride layers.

In one embodiment, the semiconductor layers 103a to 103g are formed of amorphous silicon by using atomic layer deposition (ALD), plasma-enhanced atomic layer deposition (PE-ALD), or any other suitable deposition processes, such as chemical vapor deposition (CVD), physical vapor deposition (PVD), low pressure chemical vapor deposition (LPCVD), plasma-enhanced chemical vapor deposition (PECVD), or any other suitable process.

In one embodiment, after deposition, an annealing process is applied to transfer the amorphous silicon into polycrystalline silicon (polysilicon). In one embodiment, the annealing process utilizes low-temperature rapid thermal annealing such as 4 minutes at 700 degrees Celsius or any other suitable annealing processes.

The semiconductor layers 103a to 103g are doped by using in-situ doping process during the deposition. For NMOS cells, N-type of dopants, such as phosphine (PH3) or arsine (AsH3) are added during the deposition process. For PMOS cells, P-type of dopants, such as diborane (B2H6) are added during the deposition process.

In another embodiment, the semiconductor layers 103a to 103g are formed by using a polysilicon deposition process, such as a high thermal decomposition of silane (SiH4) at 580 to 650 degrees Celsius. This process forms the polysilicon layers on the surface of the sacrificial layers 110a to 110f and releases hydrogen (H2).

In another embodiment, the semiconductor layers 103a to 103g are formed by using a silicon epitaxial growth process to form single-crystalline silicon (mono-silicon) on the surface of the sacrificial layers 110a to 110f. This process may take a longer process time because the silicon layers are grown layer by layer.

The sacrificial layers 110a to 110f are formed by using deposition processes, such as atomic layer deposition (ALD), plasma-enhanced atomic layer deposition (PE-ALD), or any other suitable deposition process, such as chemical vapor deposition (CVD), physical vapor deposition (PVD), low pressure chemical vapor deposition (LPCVD), plasma-enhanced chemical vapor deposition (PECVD), or any other suitable process.

FIG. 4B shows how multiple vertical bit line holes (or openings), such as bit line holes 111a to 111c are formed by using photolithography steps to define a pattern, and then using anisotropic etching processes, such as a deep trench process or a dry etch process to etch through the multiple semiconductor layers 103a to 103g and the sacrificial layers 110a to 110f to form the vertical bit line holes 111a to 111c.

FIG. 4C shows how floating bodies, such as floating bodies 102a to 102c are formed by using or collisional plasma doping (PLAD) or plasma immersion ion implantation (PIII), gas-phase doping, or any other suitable doping processes. For NMOS cells, diborane and hydrogen (B2H6/H2) plasma is used to implant boron ions through the vertical bit line holes 111a to 111c into the N-type semiconductor layers 103a to 103g to reverse the doping to form P-floating bodies 102a to 102c. For PMOS cells, phosphine (PH3) or Arsine (AsH3) plasma is used to implant phosphorus or Arsenic ions into the P-type semiconductor layers 103a to 103g to reverse the doping to form the N− floating bodies 102a to 102c.

In one embodiment, the floating body formation requires special sidewall doping to form a P-type junction in N-type polysilicon layers, which poses significant challenges for conventional Ion Implantation or plasma doping due to its directional nature that requires electric field bias on the wafer substrate. In the following section, four innovative methods are disclosed to form a P-type junction through a polysilicon sidewall.

Spin-on with Organic or Inorganic Dopant Materials

The advantages of this method include lower cost of consumable materials and capital equipment. Spin-on track equipment is mature and readily available. This method comprises the following process steps.

Coating: Referring to FIG. 4C, Boron containing material is coated by a spin-on track after the vertical bit line holes, such as bit line holes 111a to 111c are formed. The dopant material will fill the entire vertical bit line holes 111a to 111c.

Curing: Process the wafer in an atmospheric furnace at medium temperature (300-450 degrees Celsius) in an O2 (for organic) or N2 (for inorganic) containing environment to cure the material and to form an oxidized or nitridized thin cap film to avoid Boron out-diffuse from the filled bit line holes 111a to 111c.

Drive in: Elevate the furnace temperature (950-1100 degrees Celsius) to drive in the Boron dopant to the desired junction depth to form the floating bodies, such as floating bodies 102a to 102c and at the same time transform the N-type amorphous silicon layers 103a to 103g to poly silicon.

Organic Dopant Layer Strip off: Most of the carbon polymer material should have been oxidized and vaporized during the Boron high temperature drive in step. However, plasma strip followed by solvent/sulfuric clean is still required to ensure removal of all the polymer residue. FIG. 4D shows the array structure after this process step.

Inorganic Dopant Layer Strip off: Silicon containing spin-on inorganic material will turn into silicon dioxide (SiO2) after the high temperature curing and drive in processes. However, the SiO2 film is still porous compared to the conventional Thermal Oxidation and Chemical Vapor Deposition (CVD) films. The porous SiO2 can be etched off by specific concentration of hydrogen fluoride (HF) or buffered oxide etchant (BOE). FIG. 4D shows the array structure after this process step.

### Chemical Vapor Deposition (CVD) or Atomic Layer Deposition (ALD)

The advantage of this method includes the conformal dopant layer deposition with ease of dopant layer removal. This method comprises the following process steps.

Coating: Boron containing SiO2 material is deposited by CVD or Atomic Layer Deposition (ALD) method conformally covering the entire sidewall of the bit line holes 111a to 111c.

Capping: With (i) undoped CVD/ALD thin oxide or (ii) CVD/ALD thin nitride or (iii) nitridize the top thin layer of SiO2 in a nitrogen (N2) environment during the drive-in step to form a thin nitro oxide cap layer. The exact dopant layer plus cap deposition type and thickness needs to be evaluated based on the design rule to prevent Boron dopant out diffusing and impacting the desired junction depth. However, the final deposition even with the cap layer should not close/seal the bit line opening throughout the whole bit line channel and should leave sufficient gap/opening all the way to the bottom of the bit line to facilitate the later on etch off of the dopant layer. The exact dopant layer plus cap deposition type and thickness may be evaluated based on the design rule.

Drive in: Load the wafer in an atmospheric furnace and elevate the furnace temperature (950-1100 degrees Celsius) in an N2 containing environment to drive in the Boron dopant to the desired junction depth to form the floating bodies 102a to 102c and at the same time transform the N-type amorphous silicon layers 103a to 103g to poly silicon.

Nitride Cap Strip off: First dip the wafer in a dilute HF follows by the standard phosphoric acid to strip off the Nitride Cap as well as the sacrificial Nitride layer.

Oxide Strip off: The SiO2 can be stripped off by specific concentration of HF or BOE. FIG. 4D shows the array structure after this process step.

The unconventional floating body formation and consistency control across the extremely wide and tall memory cell structures are the key enablers of the cell structure according to the invention. The formation part was described in the previous paragraphs.

The consistency of the floating body dopant concentration profile and depth across the wide horizontal plane and multiple vertical layers will be critical to ensure the performance and reliability of the cells.

The grain boundary diffusion mechanism is the first order path for dopant to be included into the silicon. Conventional semiconductor methods for dopant inclusion and distribution are widely applied by the following two methods.

### Ion Implantation

In one embodiment, a bias electrical field is applied to the ionized dopant species to bombard the silicon of either mono or poly crystalline silicon. Due to the energized dopant directional bombardment, the silicon crystalline structure is being damaged and becomes an amorphous form. At the same time, dopant species penetrated into the silicon and enclosed in the grain boundaries of the damaged depth. The doped silicon is sent through subsequent high temperature thermal processing cycles by design to repair the silicon crystalline structure and at the same time distribute the dopant gradian profile across the crystalline structure to the target depth. This method is widely used for device junction formation.

### In-Situ Doping

In one embodiment, gas phase dopant is applied during the silane (SiH4) thermal reaction during the Low-Pressure Chemical Vapor Deposition (LPCVD) around 400-600 degrees Celsius. The resulting silicon will be amorphous in small grain size with the initial dopant concentration enclosed in the small grain boundaries. The doped amorphous silicon is sent through subsequent high temperature thermal processing cycles by design to enable the silicon grain growth to the target stable grain size and at the same time redistribute the dopant across the poly crystalline structure. This method is widely used for poly gate formation.

The floating body formation, however, required dopant diffusion through the sidewall direction after the poly silicon is deposited and without the electrical bias. This disclosure covers the process steps and control parameters to achieve the optimum floating body profile with (1) stable poly silicon grain size, (2) dopant diffusion profile and depth.

After the dopant source material is deposited in the bit line channel, apply sufficient thermal energy to drive and diffuse the optimum dopant gradian into the silicon layer and at the same time facilitate the grain growth. The dopant source as previously disclosed is preferred to be SiO₂ or organic form deposited through either low temp CVD, ALD or spin-on method in the bit line channel. The source material's dopant concentration and thermal cycle will determine the optimum floating body profile.

To facilitate and achieve the optimum floating body profile, the silicon layer is preferred in amorphous form with smaller grain size by lower temperature CVD or ALD deposition process to begin to allow the dopant initial diffusion through the grain boundaries during the initial thermal cycle.

The optimum thermal cycle control parameters include an inert gas environment, such as nitrogen (N2) or argon (Ar), ramp rate, target temperature (900-1100 degrees Celsius), duration, and at target temperature duration, and so on.

FIG. 4D shows how the vertical bit line holes, such as bit line holes 111a to 111c shown in FIG. 4C, are filled with semiconductor material, such as heavily doped polysilicon to form vertical bit lines, such as vertical bit lines 101a to 101c. The semiconductor is deposited by using any suitable deposition processes, such as atomic layer deposition (ALD), plasma-enhanced atomic layer deposition (PE-ALD), chemical vapor deposition (CVD), physical vapor deposition (PVD), low pressure chemical vapor deposition (LPCVD), plasma-enhanced chemical vapor deposition (PECVD), or any other suitable processes. The semiconductor of the bit lines, such as bit lines 101a to 101c, are doped with the same type of heavy doping of the semiconductor layers 103a to 103g by using an in-situ doping process. For NMOS cells, N-type of dopants, such as phosphine (PH3) or arsine (AsH3) are added during the deposition of the bit lines. For PMOS cells, P-type of dopants, such as diborane (B2H6) are added during the deposition of the bit lines.

FIGS. 4E-F show embodiments of the process steps used to form the cell structure shown in FIG. 1C. After the process step shown in FIG. 4C is performed, a process step shown in FIG. 4E is performed in which semiconductor layers 107a to 107c such as polysilicon or silicon are formed on the sidewall of the vertical bit line holes 111a to 111c by using the deposition processes described with reference to FIG. 4A, such as atomic layer deposition (ALD), plasma-enhanced atomic layer deposition (PE-ALD), or any other suitable deposition processes, or by using epitaxial growth processes to grow a single-crystalline silicon layer. The semiconductor layers 107a to 107c are doped with the same type of heavy doping as the semiconductor layers 103a to 103g by using an in-situ doping process. For NMOS cells, N-type of dopants, such as phosphine (PH3) or arsine (AsH3) are added during the deposition of the semiconductor layers 107. For PMOS cells, P-type of dopants, such as diborane (B2H6) are added during the deposition of the semiconductor layers 107.

FIG. 4F shows how the vertical bit line holes 111a to 111c are filled with a high melting point metal, such as tungsten (W) to form vertical bit lines, such as vertical bit lines 101a to 101c. The tungsten is deposited by using any suitable deposition processes, such as chemical vapor deposition (CVP) reaction with tungsten hexafluoride (WF6) plus hydrogen (H2) and silane (SiH4). The metal bit lines 101a to 101c reduce the bit line resistance.

Before depositing the metal in the vertical bit line holes 111a to 111c, a glue layer (not shown) such as a titanium and titanium nitride (Ti/TiN) layer may be formed on the surface of the semiconductor layer 107a to 107c. The glue layer helps to prevent peeling of the metal bit lines 101a to 101c from the semiconductor layer 107a to 107c and improve the reliability. The TiN and Ti layers are formed by using chemical vapor deposition (CVD) and ion metal plasma (IMP) physical vapor deposition (PVD) process, respectively. In various embodiments, a glue layer, such as the glue layer applied to the semiconductor layer 107 is optional and can be omitted if desired.

FIG. 4G shows how the sacrificial layers 110a to 110f are selectively removed by using an isotropic etching process such as wet etching. If the sacrificial layers 110a to 110f are oxide layers (SiO2), they can be etched by using buffered hydrofluoric acid (HF), ammonium acid (NH4F) or a mixture of hydrofluoric acid (HF) and nitric acid (HNO3). If the sacrificial layers 110a to 110f are nitride layers (Si3N4), they can be etched by using concentrated hot orthophosphoric acid (H3PO4) at a temperature of 150 to 180 degrees Celsius.

FIG. 4H shows how gate dielectric layers 105a to 105f, such as a gate oxide (SiO2) layers or a high-K material layers, such as hafnium oxide (HfO2), zirconium oxide (ZrO2), or titanium oxide (TiO2) are formed on the surface of the sidewall of the spaces that are previously occupied by the sacrificial layers 110a to 110f. The gate dielectric layers 105a to 105f are formed by using thermal oxidation or dry oxidation to grow silicon oxide (SiO2) layers on the surfaces of the semiconductor layers 103a to 103g and the vertical bit lines such as 101a to 101c, or using atomic layer deposition (ALD), plasma-enhanced atomic layer deposition (PE-ALD), or any other suitable deposition processes to deposit a thin layer of the gate dielectric material on the surface of the spaces.

FIG. 4I shows how the spaces that were previously occupied by the sacrificial layers 110a to 110f are filled with metal material, such as tungsten (W), tantalum (Ta), titanium (Ti), niobium (Nb) for NMOS cells, or ruthenium (Ru) for PMOS cells, or the composite of metal nitride such as WN, TaN, and TiN, or heavily doped polysilicon to form the metal word lines (or gates) 104a to 104f of the cell transistors. The metal word lines 104a to 104f are formed by using deposition processes, such as atomic layer deposition (ALD), plasma-enhanced atomic layer deposition (PE-ALD), chemical vapor deposition (CVD), physical vapor deposition (PVD), low pressure chemical vapor deposition (LPCVD), plasma-enhanced chemical vapor deposition (PECVD), or any other suitable processes. As a result, the array comprising a floating-body cell structure as shown in FIG. 1C is formed.

FIG. 4J shows a table providing a summary of process conditions and materials for use with the process steps described and shown in FIGS. 4A-I. It should be noted that these process conditions and materials are exemplary, and that other suitable process conditions and materials can be used to achieve the same process results. Thus, such modifications and variations are within the scope of the invention. The table illustrated in FIG. 4J shows process steps 401, process type 402, temperature 403 used for the process step, chemical material 404 used in the process step, and concentration (CONC) 405 of the material.

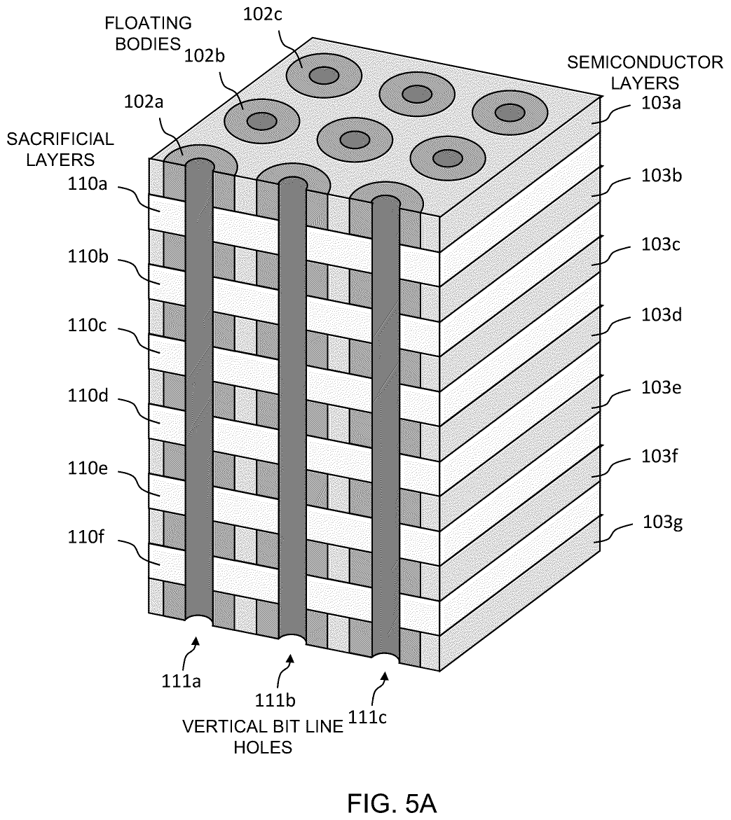

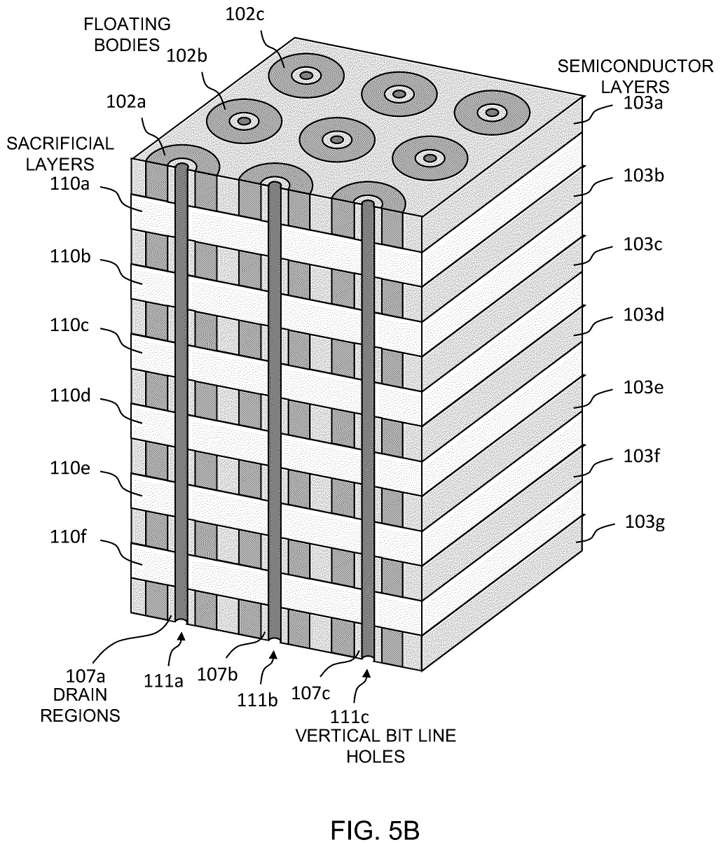

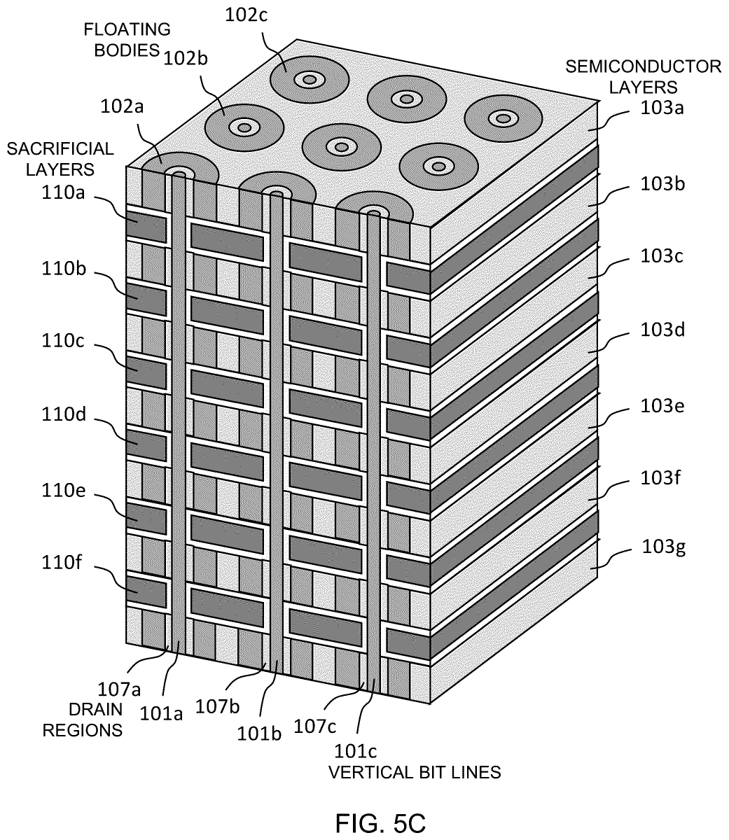

FIGS. 5A-C show embodiments of brief process steps to form an array using the cell structure shown in FIG. 1E according to the invention.

FIG. 5A shows an array structure that is formed after the process step shown in FIGS. 4A-C. The reader is referred to the FIGS. 4A-C for a detailed description for forming the array structure shown in FIG. 5A.

FIG. 5B shows how drain regions, such as 107a to 107c are formed by using plasma doping (PLAD) or gates-phase doping or any other suitable doping processes to dope the opposite type of heavy dopants into the floating bodies, such as floating bodies 102a to 102c. This doping process is performed through the vertical bit line holes, such as bit line holes 111a to 111c. For NMOS cells, phosphine (PH3) or Arsine (AsH3) plasma is used to implant phosphorus or Arsenic ions into the P-type floating bodies, such as 102a to 102c to reverse the doping to form N+ drain regions, such as 107a to 107c. For PMOS cells, diborane and hydrogen (B2H6/H2) plasma is used to implant boron ions into the N-type floating bodies, such as 102a to 102c to reverse the doping to form a P+ drain regions, such as 107a to 107c.

After the process steps described with reference to FIG. 5B are performed, the process steps shown in FIGS. 4F-I are performed to form the array structure shown in FIG. 5C. The reader is referred to FIGS. 4F-I for the detailed description of those process steps. As a result, an array comprising a floating-body cell structure is formed as shown in FIG. 1E is formed.

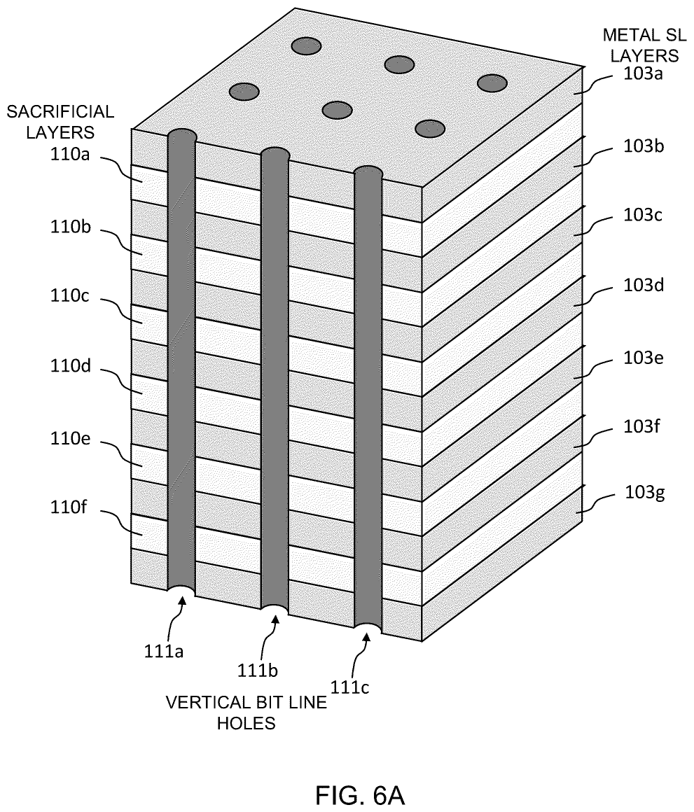

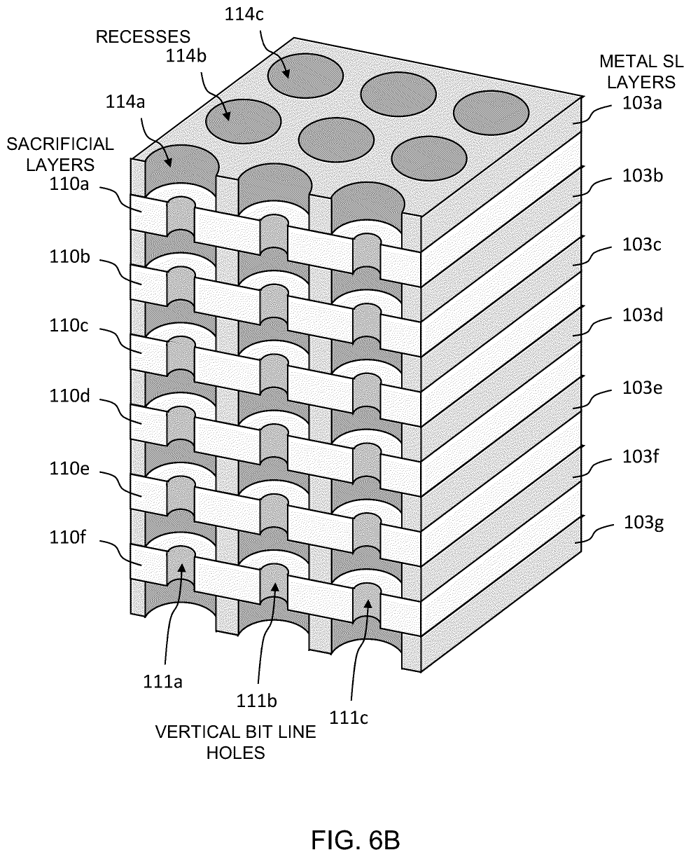

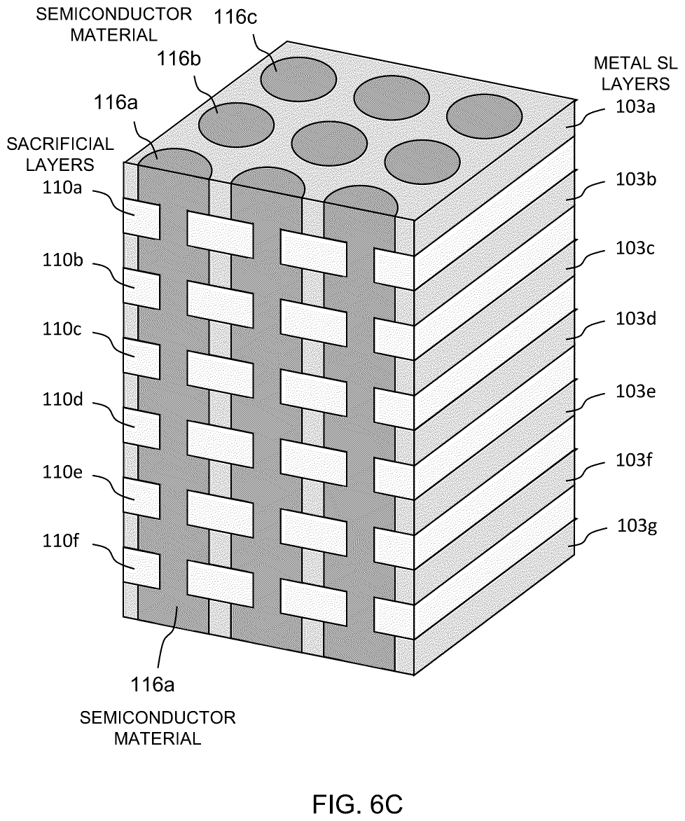

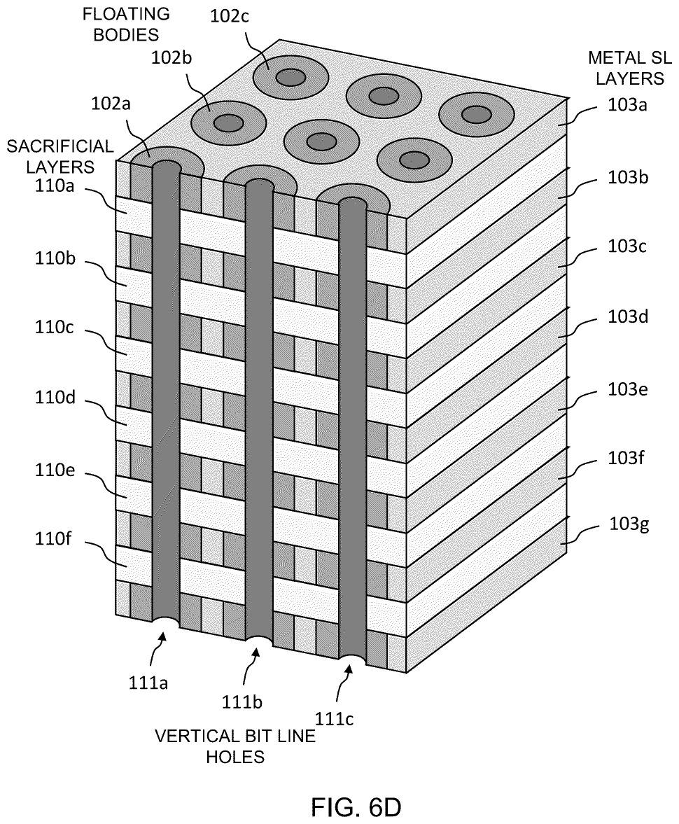

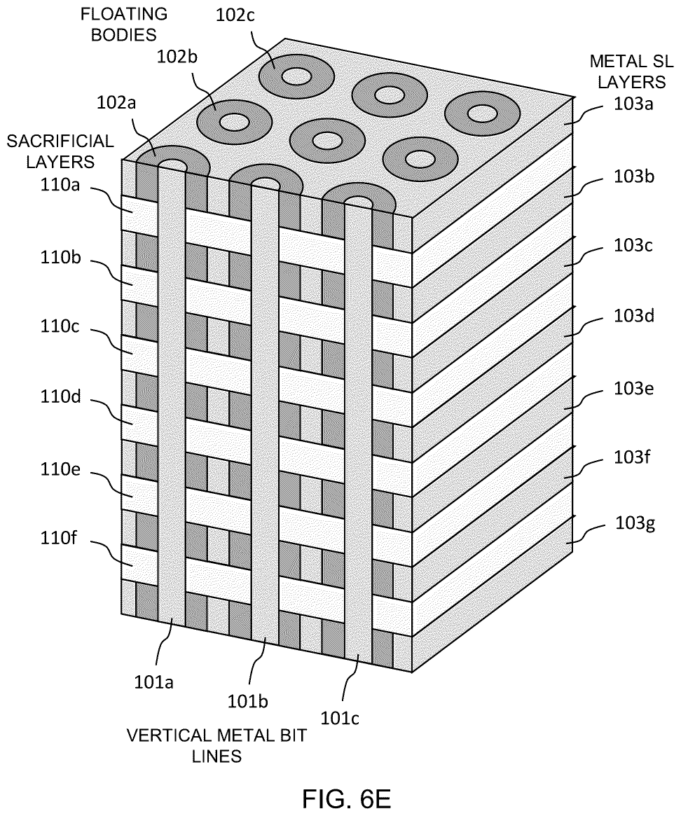

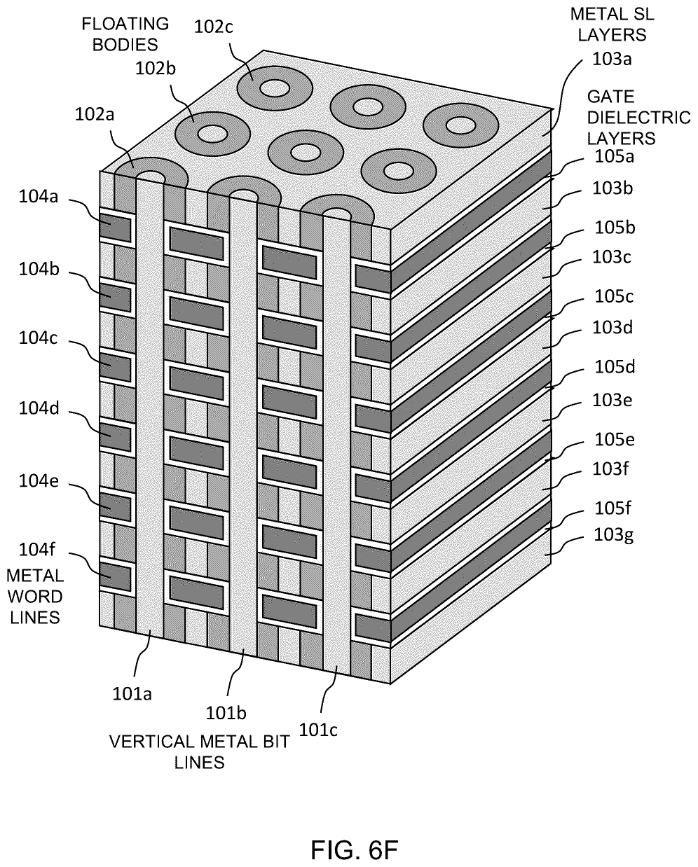

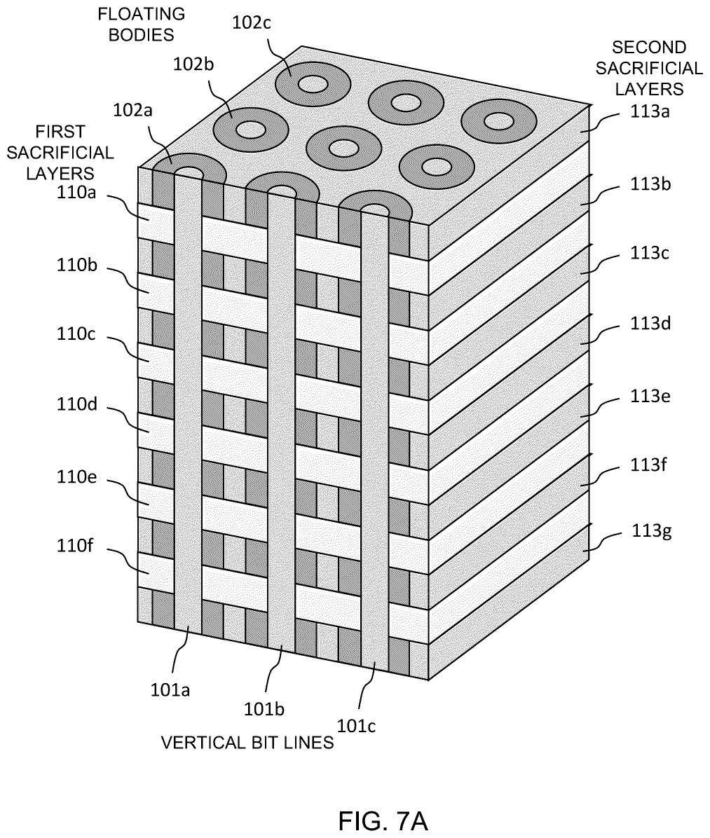

FIGS. 6A-F show embodiments of brief process steps to form an array using the cell structure shown in FIG. 1I according to the invention.

FIG. 6A shows an array structure that is formed after the process steps shown and described with reference to FIGS. 4A-B. The reader is referred to FIGS. 4A-B for the detailed description of the process steps to form the array structure shown in FIG. 6A. In this embodiment, source line (SL) layers 103a to 103g are formed from high melting point metal, such as tungsten (W). The tungsten is deposited by using any suitable deposition process, such as chemical vapor deposition (CVP) reaction with tungsten hexafluoride (WF6) plus hydrogen (H2) and silane (SiH4).

FIG. 6B shows how an isotropic etching process, such as wet etching is performed through the vertical bit line holes, such as 111a to 111c to selectively etch the sacrificial layers 110a to 110f to form recesses, such as recesses 114a to 114c. The dimension of the recesses 114a to 114c are controlled by the etching rate of the etching solution and the etching time. If the first sacrificial layers 110a to 110f are formed of silicon oxide (SiO2), they can be etched by using buffered hydrofluoric acid (HF) with ammonium acid (NH4F) or a mixture of hydrofluoric acid (HF) and nitric acid (HNO3).

FIG. 6C shows how the recesses, such as recesses 114a to 114c and the vertical bit line holes, such as vertical bit line holes 111a to 111c are filled with semiconductor material 116, such as polysilicon or silicon. In one embodiment, the polysilicon is formed by using a polysilicon deposition process comprising the silicon epitaxial growth process described with reference to FIG. 4A. The reader is referred to FIG. 4A for a detailed description of a polysilicon deposition process. The semiconductor material 116 is doped by using an in-situ doping process. For NMOS cells, N-type of dopants, such as phosphine (PH3) or arsine (AsH3) are added during the deposition process. For PMOS cells, P-type of dopants, such as diborane (B2H6) added during the deposition process.

FIG. 6D shows how an anisotropic etching process, such as dry etching is performed using the sacrificial layers 110a to 110f as hard masks to selectively etch the semiconductor material 116 to re-form the vertical bit line holes, such as vertical bit line holes 111a to 111c. Because this etching process is self-aligned, a high yield can be achieved. After the vertical bit line holes, such as vertical bit line holes 111a to 111c are re-formed, the semiconductor material 116 in the recesses (e.g., such as recesses 114a to 114c) becomes the floating bodies, such as floating bodies 102a to 102c of the cell transistors.

FIG. 6E shows how the vertical bit line holes, such as 111a to 111c are filled with high meting point metal, such as tungsten (W) to form the vertical metal bit lines, such as metal bit lines 101a to 101c. The tungsten is deposited by using any suitable deposition process, such as chemical vapor deposition (CVP) reaction with tungsten hexafluoride (WF6) plus hydrogen (H2) and silane (SiH4).

After filling the vertical bit line holes 111 to form the metal bit lines 101, the process steps shown and described with reference to FIGS. 4G-I are performed to form the array structure shown in FIG. 6F. For example, the sacrificial layers 110 are removed, gate dielectric layers 105 are deposited, and the metal word lines 104 are formed. The reader is referred to FIGS. 4G-I for the detailed description of those process steps. In this embodiment, the vertical bit lines, such as metal bit lines 101a to 101c and the source line layers 103a to 103g are formed of metal. As a result, the array comprising the floating-body cell structure shown in FIG. 1I is formed.

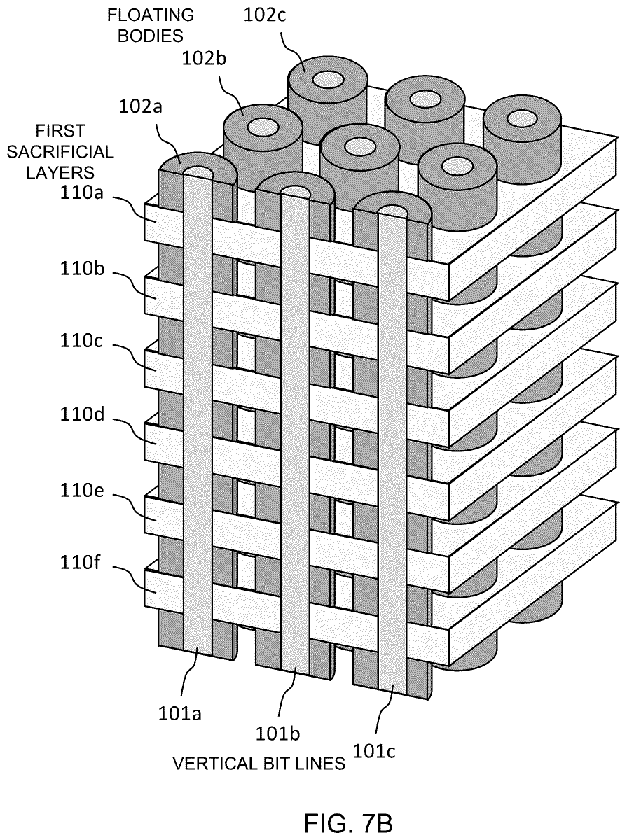

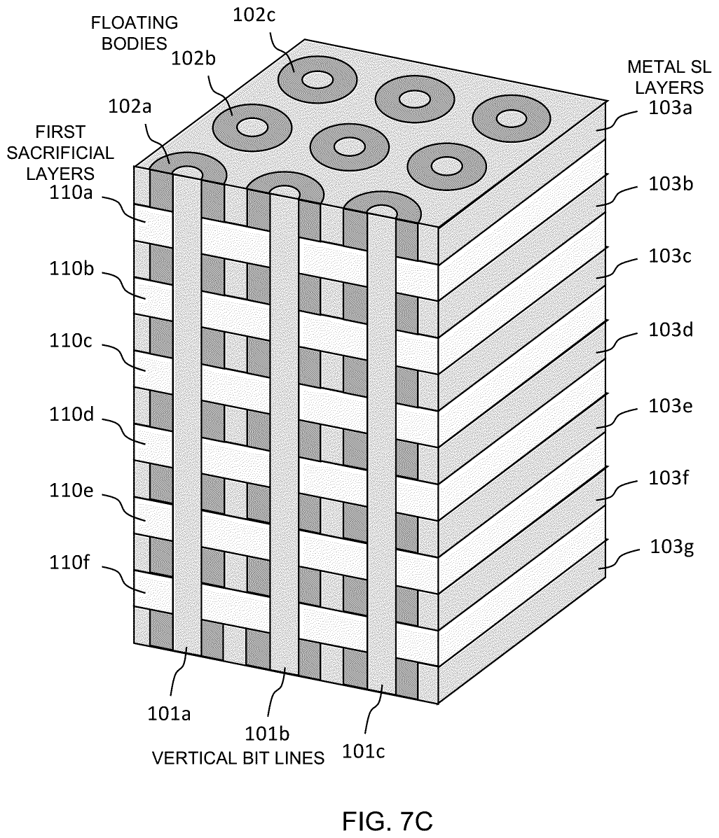

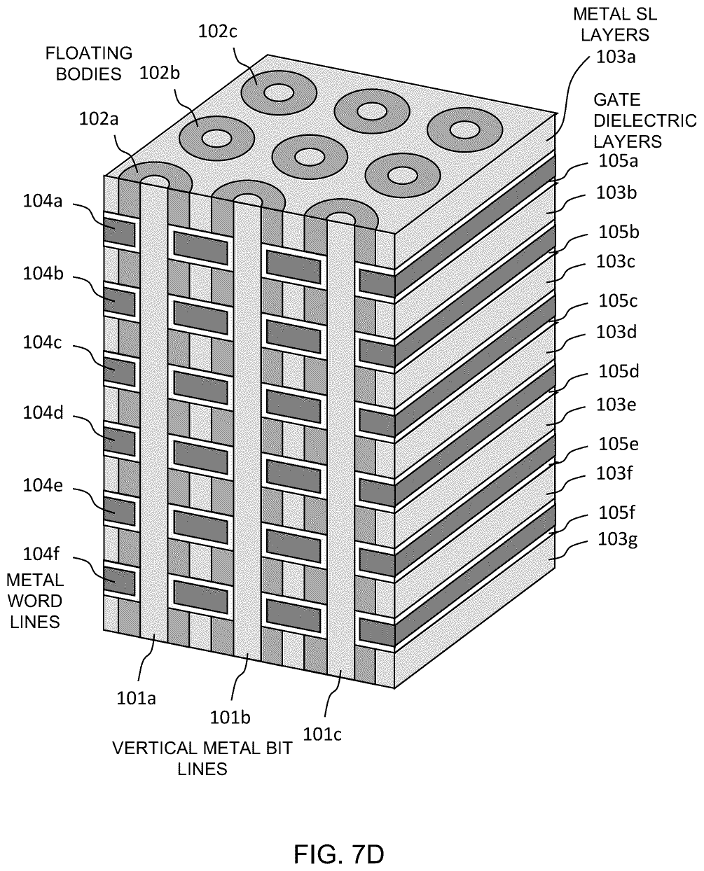

FIGS. 7A-D show embodiments of brief process steps to form an array comprising the cell structure shown in FIG. 1I according to the invention.

FIG. 7A shows an array structure constructed after performing the process steps shown in FIGS. 4A-D. The reader is referred to FIGS. 4A-D for the detailed description of those process steps. In this embodiment, the layers 113a to 113g are formed of a second sacrificial material, such as oxide or nitride. The second sacrificial layers 113a to 113g and the first sacrificial layers 110a to 110f are configured to have different etching selectivity. For example, in one embodiment, the first sacrificial layers 110a to 110f are formed of oxide and the second sacrificial layers 103a to 103g are formed of nitride.

FIG. 7B shows how the second sacrificial layers 113a to 113g are selectively removed by using an isotropic etching process, such as wet etching. If the second sacrificial layers 113a to 113g are formed of silicon oxide (SiO2), they can be etched by using buffered hydrofluoric acid (HF) with ammonium acid (NH4F) or a mixture of hydrofluoric acid (HF) and nitric acid (HNO3).

FIG. 7C shows how a high melting point metal, such as tungsten (W) is deposited to fill the spaces that are previously occupied by the second sacrificial layers 113a to 113g to form the metal source line layers 103a to 103g. The tungsten is deposited by using any suitable deposition process, such as chemical vapor deposition (CVP) reaction with tungsten hexafluoride (WF6) plus hydrogen (H2) and silane (SiH4).

After the process of depositing the metal describe above, the process steps shown and described with reference to FIGS. 4G-I are performed to form the array structure shown in FIG. 7D. For example, the sacrificial layers 110 are removed, gate dielectric layers 105 are deposited, and the metal word lines 104 are formed. The reader is referred to FIGS. 4G-I for the detailed description of those process steps. As a result, the array comprising a floating-body cell structure shown in FIG. 1I is formed.

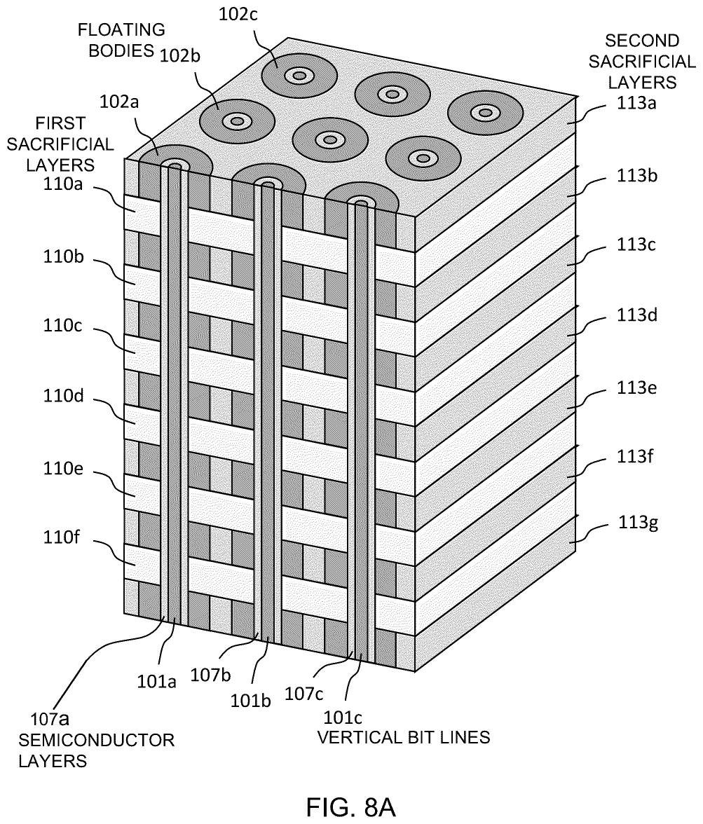

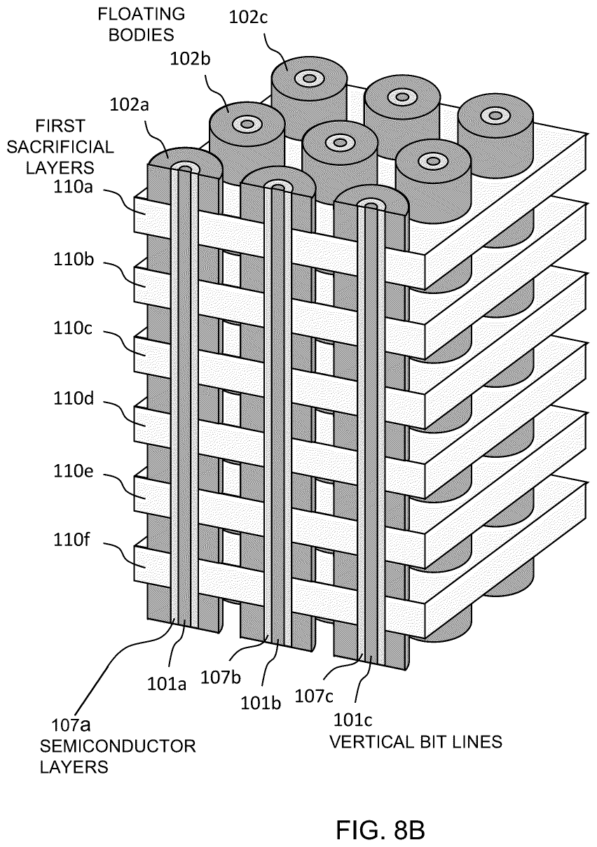

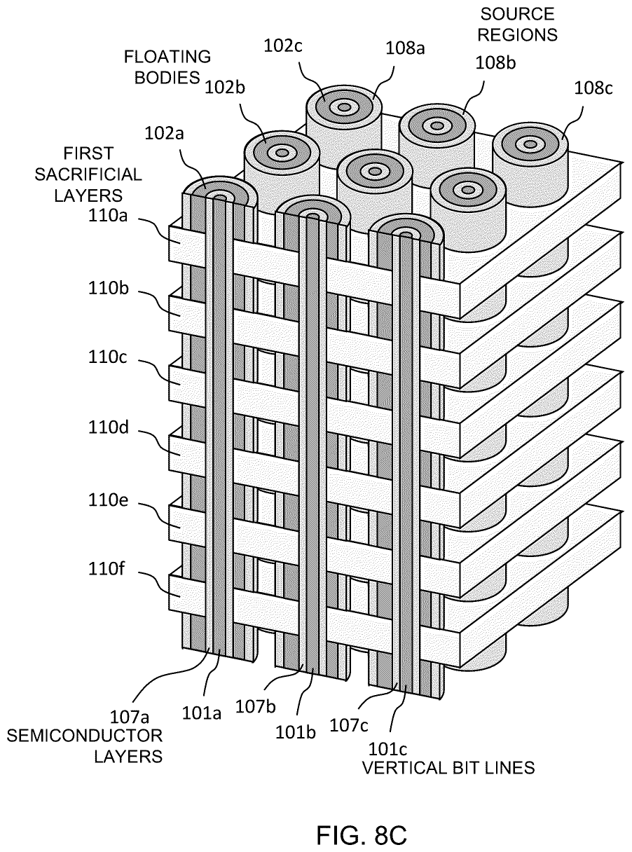

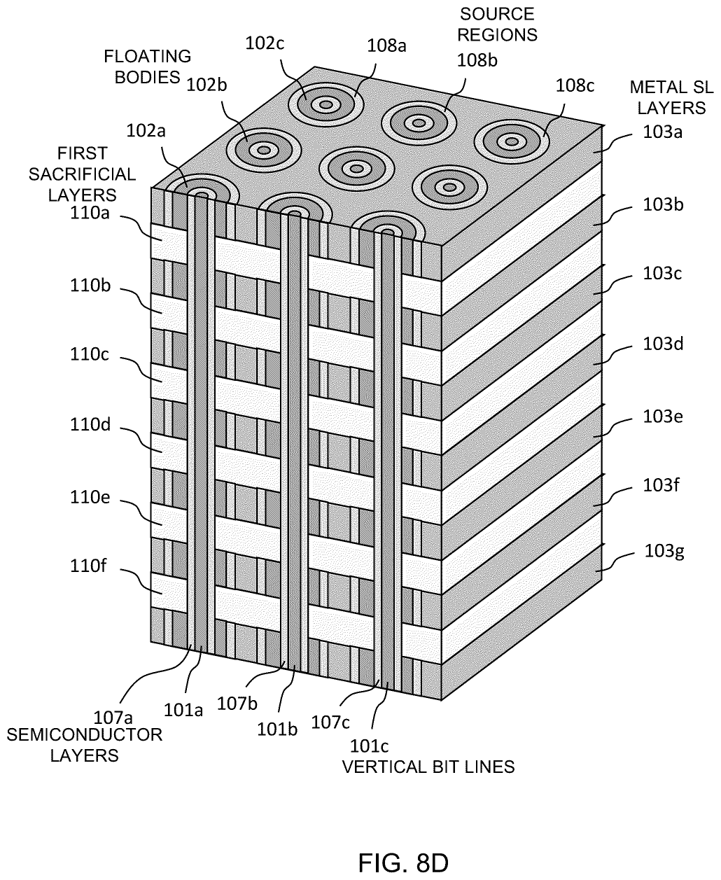

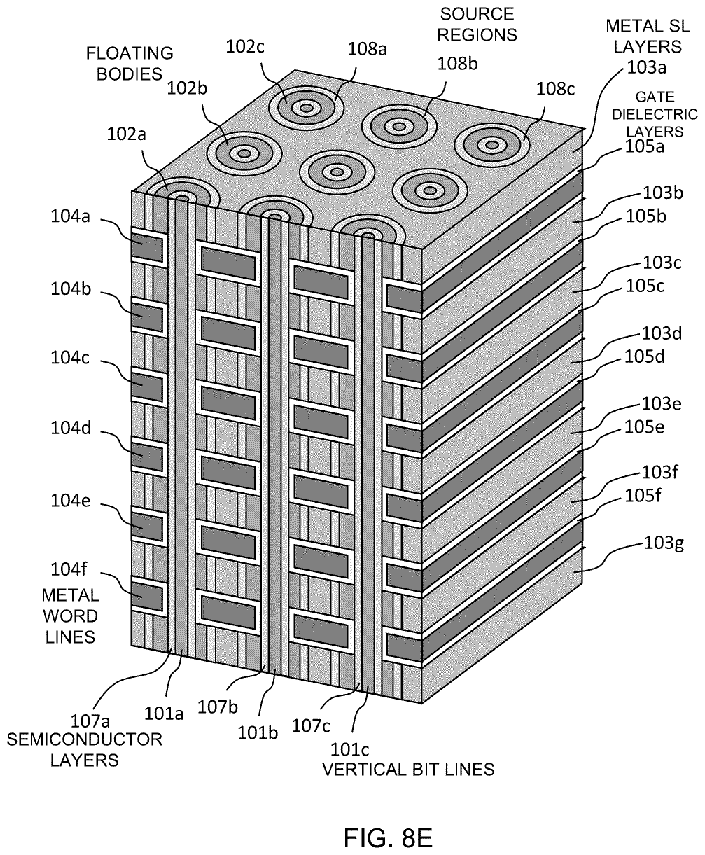

FIGS. 8A-E show another embodiment of brief process steps to form an array comprising the cell structure shown in FIG. 1G according to the invention.

FIG. 8A shows an array structure that is formed after performing the process steps shown in FIGS. 4A-F. The reader is referred to FIGS. 4A-F for the detailed description of the process steps to form this array structure. In this embodiment, the layers 113a to 113g are formed of a second sacrificial material, such as oxide or nitride. The second sacrificial layers 113a to 113g and the first sacrificial layers 110a to 110f are configured to have different etching selectivity. For example, in one embodiment, the first sacrificial layers 110a to 110f are formed of oxide and the second sacrificial layers 103a to 103g are formed of nitride.

FIG. 8B shows how the second sacrificial layers 113a to 113g are selectively removed by using an isotropic etching process, such as wet etching. If the second sacrificial layers 113a to 113g are formed of silicon oxide (SiO2), they can be etched by using buffered hydrofluoric acid (HF) with ammonium acid (NH4F) or a mixture of hydrofluoric acid (HF) and nitric acid (HNO3).

FIG. 8C shows how source regions, such as 108a to 108c are formed by using plasma doping (PLAD) or a gas-phase doping process or any other suitable doping process with the opposite type of heavy dopants to reverse the doping type of the floating bodies, such as 102a to 102c.

FIG. 8D show how a high melting point metal, such as tungsten (W) is deposited to fill the spaces that were previously occupied by the second sacrificial layers 113a to 113g to form the metal source line layers 103a to 103g. The tungsten is deposited by using any suitable deposition process, such as chemical vapor deposition (CVP) reaction with tungsten hexafluoride (WF6) plus hydrogen (H2) and silane (SiH4).

After the metal is deposited as described above, the process steps shown in FIGS. 4G-I are performed to form the array structure shown in FIG. 8E. For example, the first sacrificial layers 110 are removed, gate dielectric layers 105 are deposited, and the metal word lines 104 are formed. The reader is referred to FIGS. 4G-I for the detailed description of those process steps. As a result, the array comprising a floating-body cell structure shown in FIG. 1G is formed.

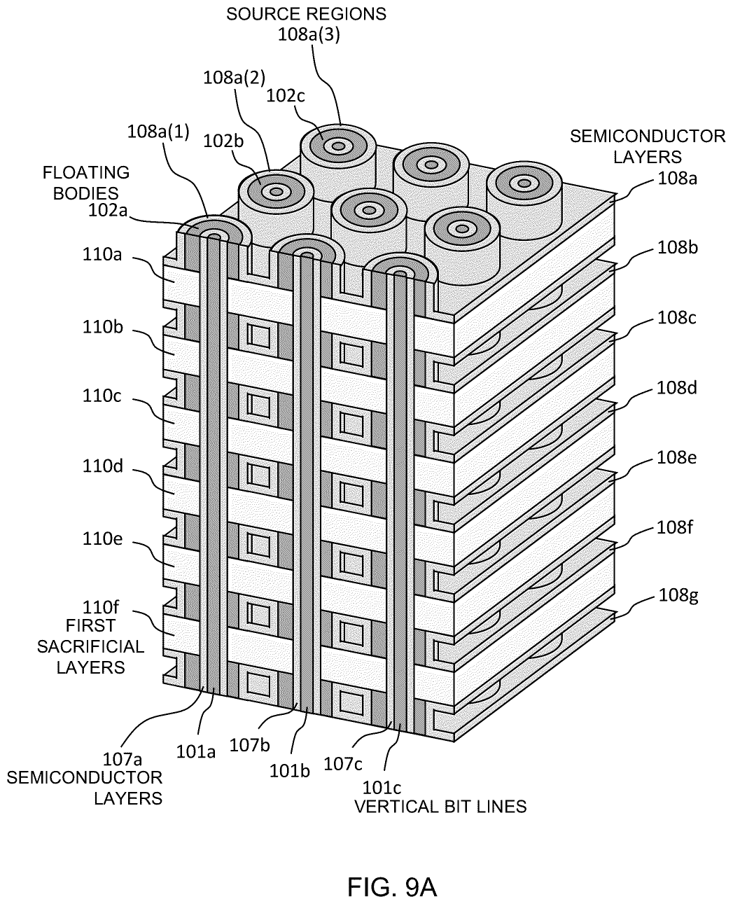

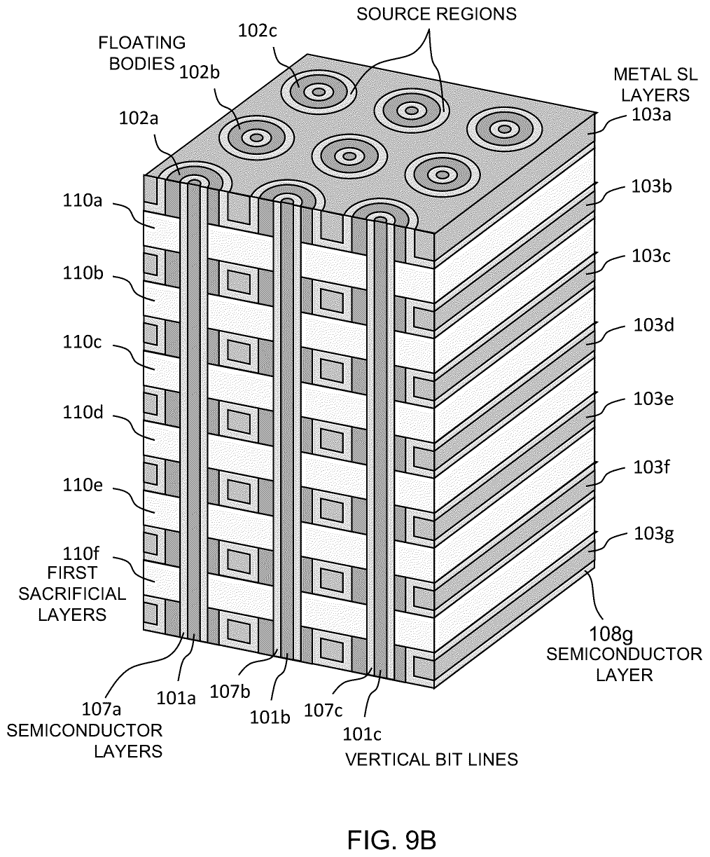

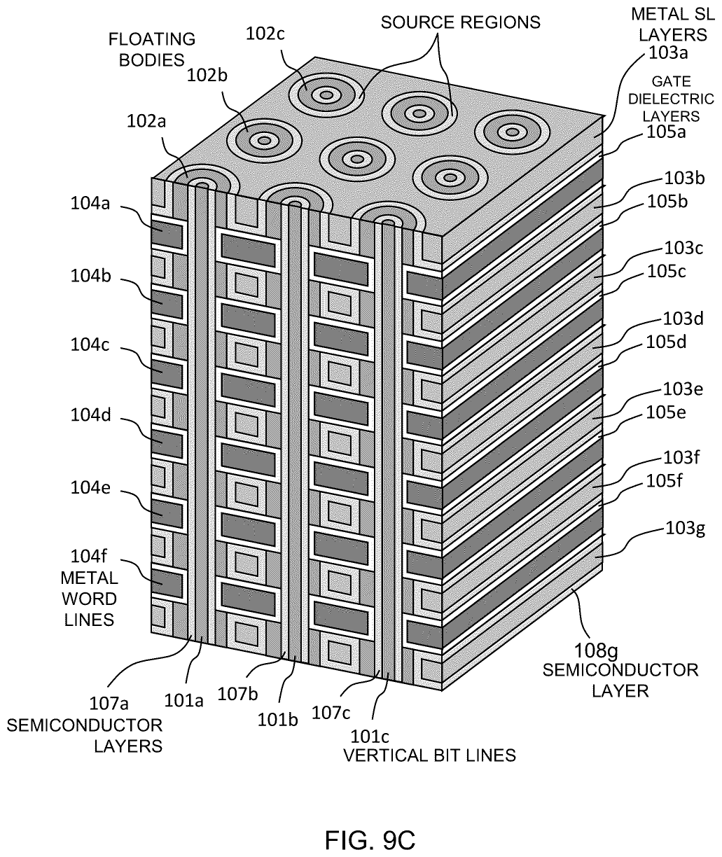

FIGS. 9A-C show an alternative embodiment for forming the source regions, such as 108a to 108c for the array having the cell structure shown in FIG. 1G. After the process steps shown and described with reference to FIG. 8B are performed, the process steps shown in FIG. 9A are performed.

FIG. 9A shows how semiconductor layers 108a-g, such as polysilicon or silicon are formed on the surface of the sidewall of the spaces that are previously occupied by the second sacrificial layers 113a to 113g. Each semiconductor layer 108 forms source regions, such as source regions 108a(1) to 108a(3) on the sidewalls of the floating bodies, such as floating bodies 102a to 102c.

In one embodiment, the semiconductor layers 108 are formed by the polysilicon deposition process, or the silicon epitaxial growth process as described with reference to FIG. 4A. The semiconductor layers 108 are doped using an in-situ doping process. For NMOS cells, N-type of dopants, such as phosphine (PH3) or arsine (AsH3) are added during the deposition process. For PMOS cells, P-type of dopants, such as diborane (B2H6) are added during the deposition process.

FIG. 9B shows how a high melting point metal, such as tungsten (W) is deposited to fill the spaces that were previously occupied by the second sacrificial layers 113a to 113g to form the metal source line layers 103a to 103g. The tungsten is deposited by using any suitable deposition process, such as chemical vapor deposition (CVP) reaction with tungsten hexafluoride (WF6) plus hydrogen (H2) and silane (SiH4). After depositing the metal, the process steps shown and described with reference to FIGS. 4G-I are performed to form the array structure shown in FIG. 9C. For example, the first sacrificial layers 110 are removed, gate dielectric layers 105 are deposited, and the metal word lines 104 are formed. The reader is referred to FIGS. 4G-I for the detailed description of those process steps.

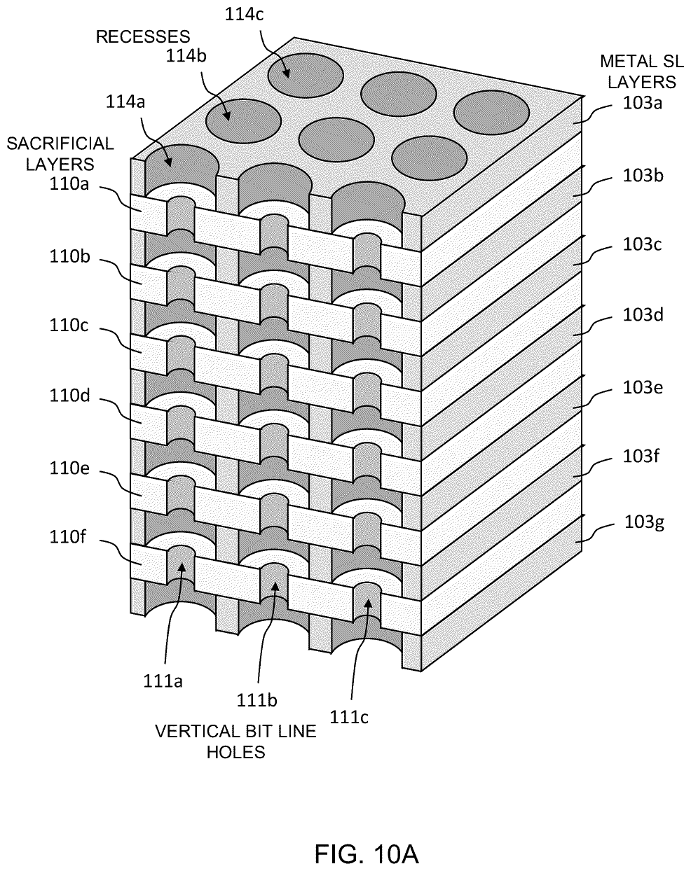

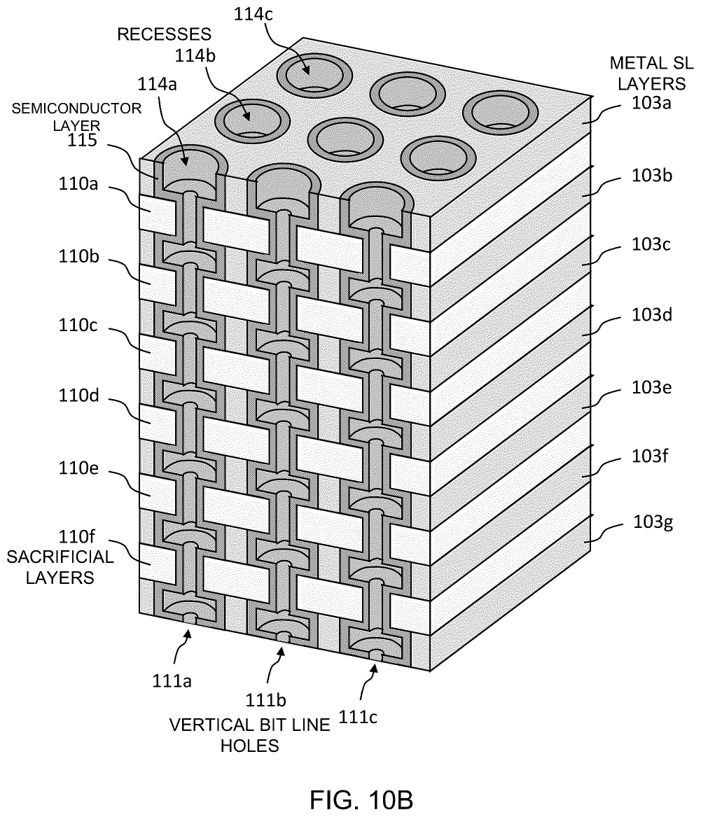

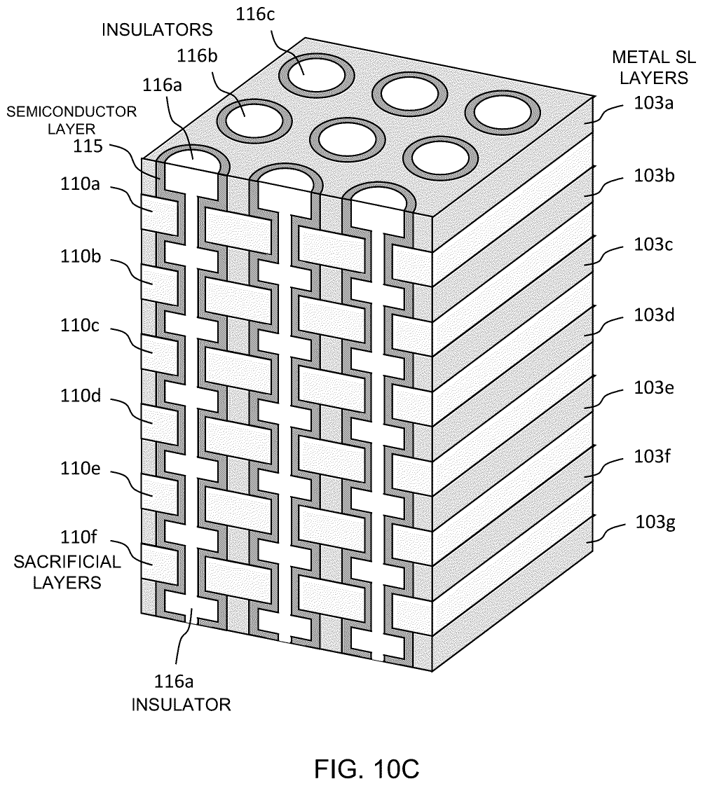

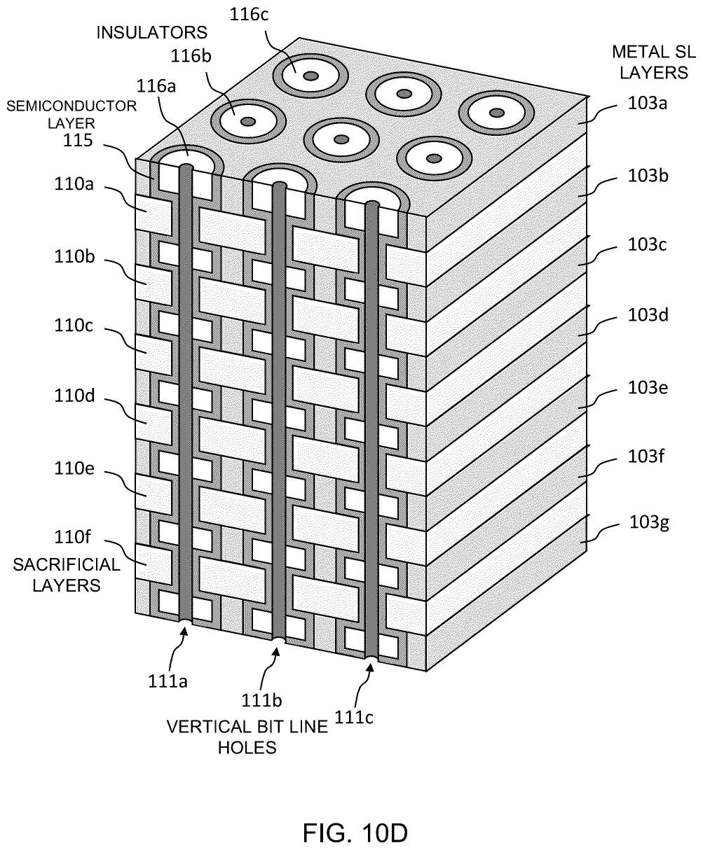

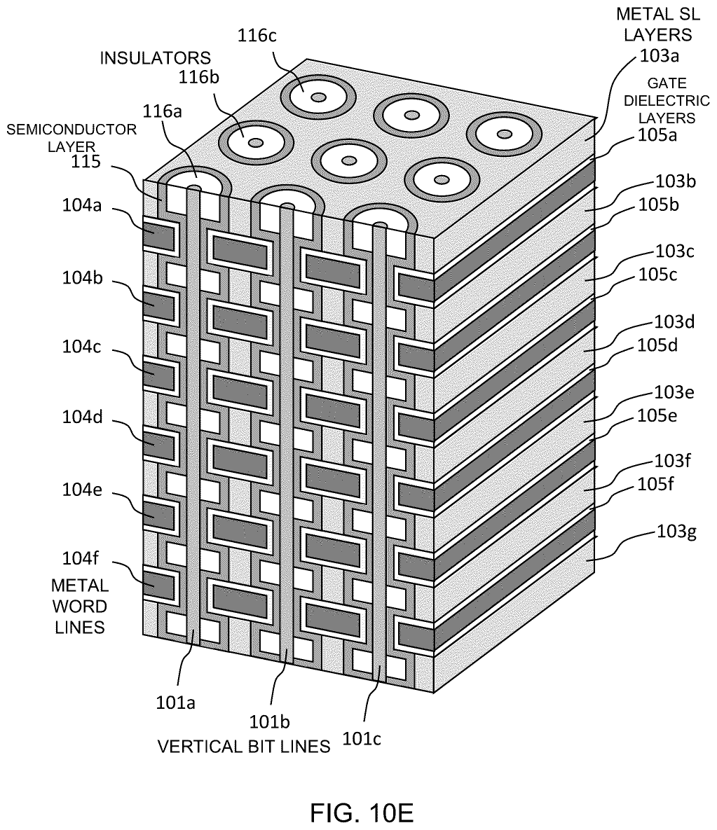

FIGS. 10A-E show another embodiment of brief process steps that are performed to form an array comprising the cell structure shown in FIG. 1K according to the invention.

FIG. 10A shows an array structure constructed after performing the process steps shown in FIGS. 6A-B. The reader is referred to FIGS. 6A-B for the detailed description of the process steps performed to form this array structure.

FIG. 10B shows how a semiconductor layer 115, such as silicon, polysilicon, silicon germanium (SiGe), indium gallium zinc oxide (IGZO), tungsten-doped indium oxide semiconductor, or any other suitable semiconductor material is formed on the surface of the sidewalls of the recesses 114, such as recesses 114a to 114c and the vertical bit line holes, such as 111a to 111c by using an epitaxial process or a deposition process as described with reference to FIG. 4A. The reader is referred to FIG. 4A for the detailed description of those processes.

FIG. 10C shows that after the semiconductor layer 115 is formed, an insulator material 116, such as oxide or nitride is deposited to fill the recesses, such as the recesses 114a to 114c and the vertical bit line holes 111a to 111c.

FIG. 10D shows how an anisotropic etching process, such as dry etching is performed using the sacrificial layers 110a to 110f and the semiconductor layer 115 as hard masks to selectively etch the insulator material 116 inside the vertical bit line holes, such as bit line holes 111a to 111c. Because this etching process is self-aligned, the process achieves a high yield.

After the etching process described above, the vertical bit line holes, such as bit line holes 111a to 111c are filled with a conductor material, such as metal or polysilicon by using a deposition process to form the vertical bit lines such as bit lines 101a to 101c. Then, the process steps shown and described with reference to FIGS. 4G-I are performed to form the array structure shown in FIG. 10E. For example, the first sacrificial layers 110 are removed, gate dielectric layers 105 are deposited, and the metal word lines 104 are formed. The reader is referred to FIGS. 4G-I for the detailed description of those process steps. As a result, the array comprising a floating-body cell structure as shown in FIG. 1K is formed.

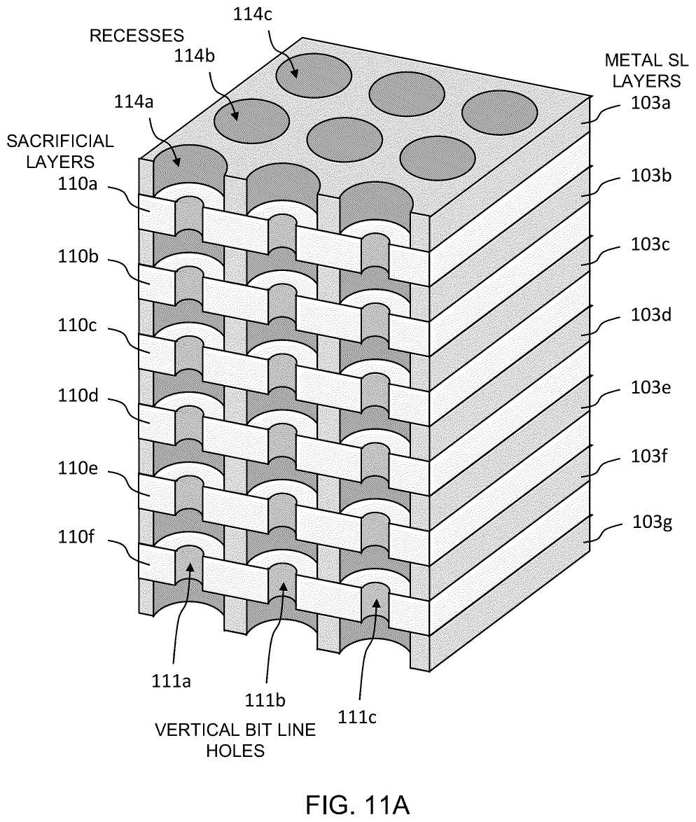

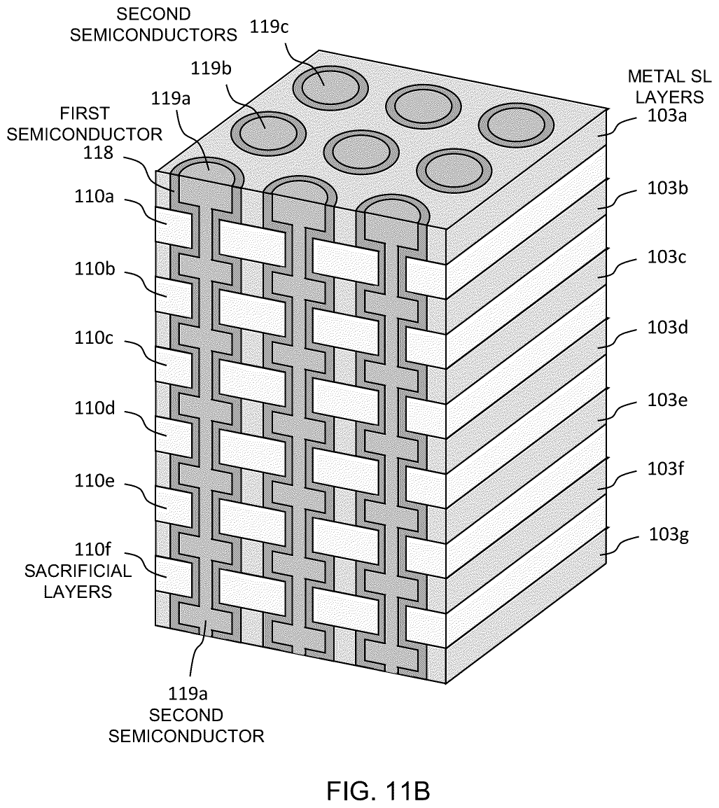

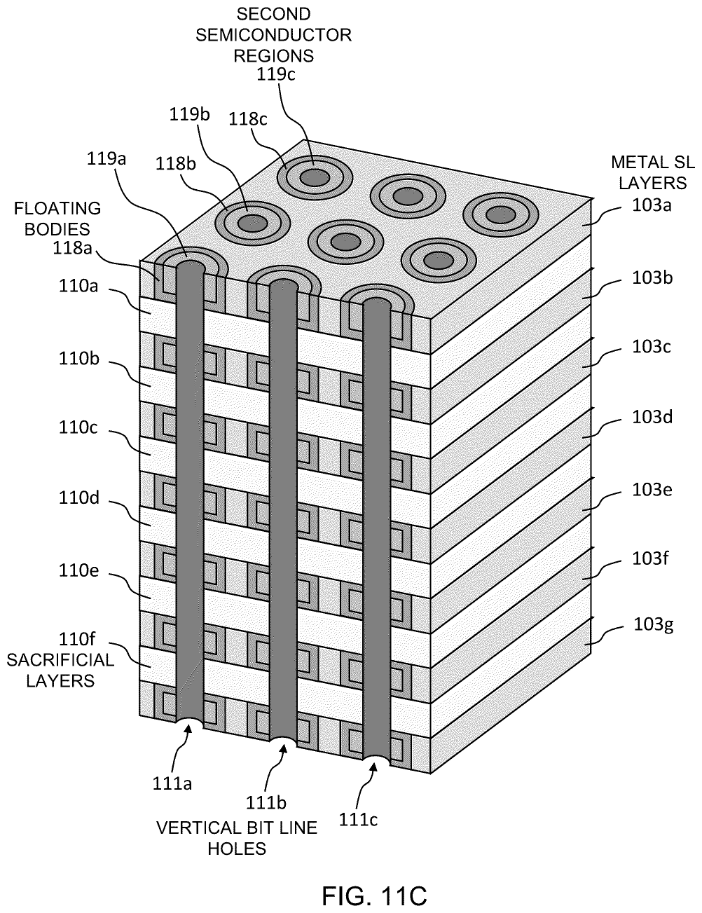

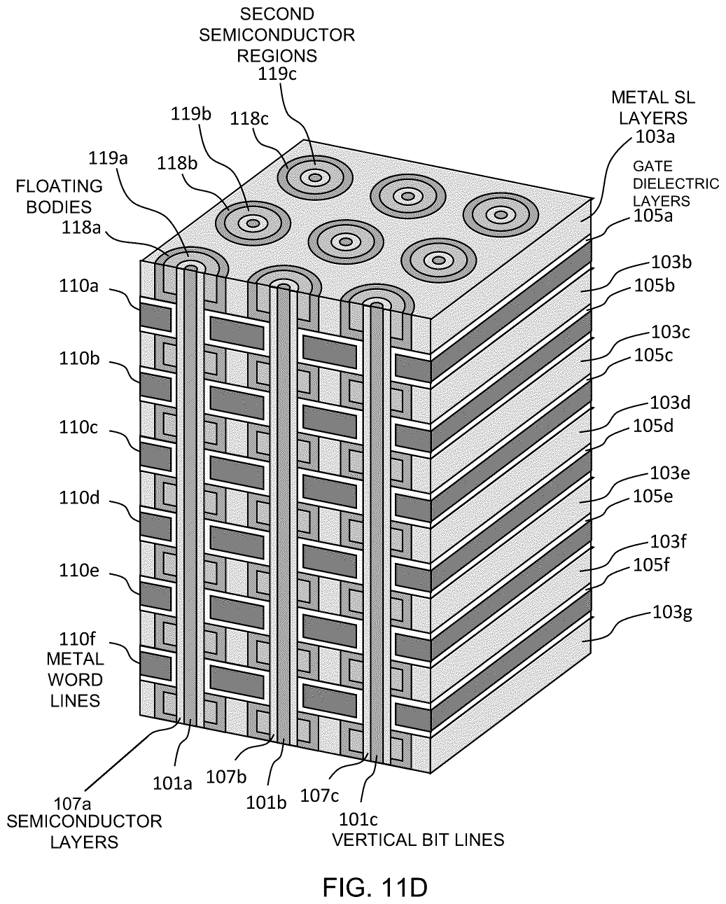

FIGS. 11A-D show another embodiment of brief process steps configured to form an array comprising the cell structure shown in FIG. 1M according to the invention.

FIG. 11A shows an array structure that results after performing the process steps shown in FIGS. 6A-B. The reader is referred to FIGS. 6A-B for the detailed description of the process steps performed to form this array structure.

FIG. 11B shows how a first semiconductor layer 118, such as silicon or polysilicon is formed on the surface of the sidewalls of the recesses, such as recesses 114a to 114c and the vertical bit line holes, such as bit line holes 111a to 111c by using a silicon epitaxial process or a polysilicon deposition process as described with reference to FIG. 4A. The reader is referred to FIG. 4A for the detailed description of those processes.

After the first semiconductor layer 118 is formed, a second semiconductor material 119 is deposited to fill the recesses, such as recesses 114a to 114c and the vertical bit line holes, such as bit line holes 111a to 111c. In one embodiment, the second semiconductor material 119 is different from the first semiconductor layer 118. For example, in one embodiment, the first semiconductor layer 118 is formed of silicon or polysilicon, and the second semiconductor material 119 comprises silicon germanium (SiGe), silicon carbide (SiC), or any other suitable semiconductor material.

FIG. 11C shows how an anisotropic etching process, such as dry etching is performed using the sacrificial layers 110a to 110f as hard masks to selectively etch the semiconductor layer 118 and the second semiconductor material 119 inside the vertical bit line holes, such as bit line holes 111a to 111c. Because this etching process is self-aligned, it achieves high process yield. After the vertical bit line holes, such as bit line holes 111a to 111c are formed, the semiconductor layers 118a to 118c become the individual floating bodies of each cell, and the second semiconductor materials 119a to 119c become the second semiconductor regions for electric charge storage.

After the etching process describe above, the process steps shown in FIGS. 4E-I are performed to form the array structure shown in FIG. 11D. For example, the first sacrificial layers 110 are removed, gate dielectric layers 105 are deposited, the metal word lines 104 are formed, the semiconductor layers 107 are deposited and the vertical bit line 101 are formed. The reader is referred to FIGS. 4E-I for the detailed description of those process steps. As a result, the array shown in FIG. 11D comprising the floating-body cell structure shown in FIG. 1M is formed.

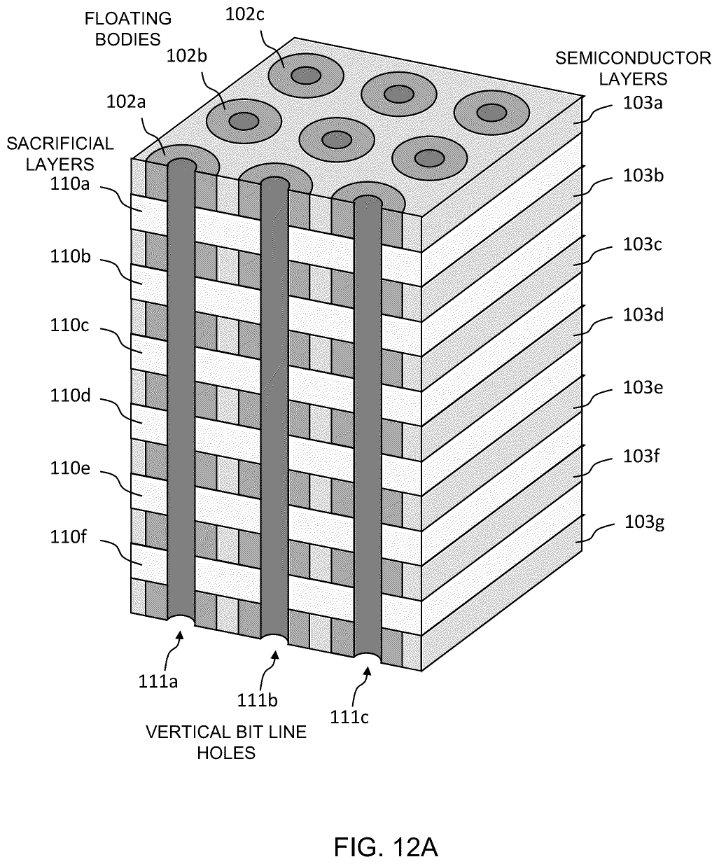

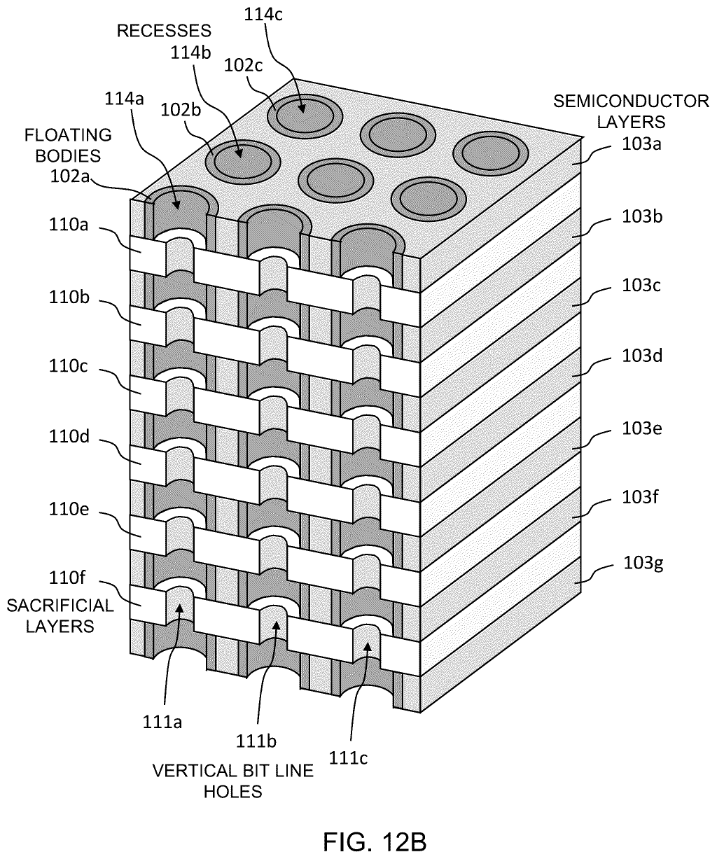

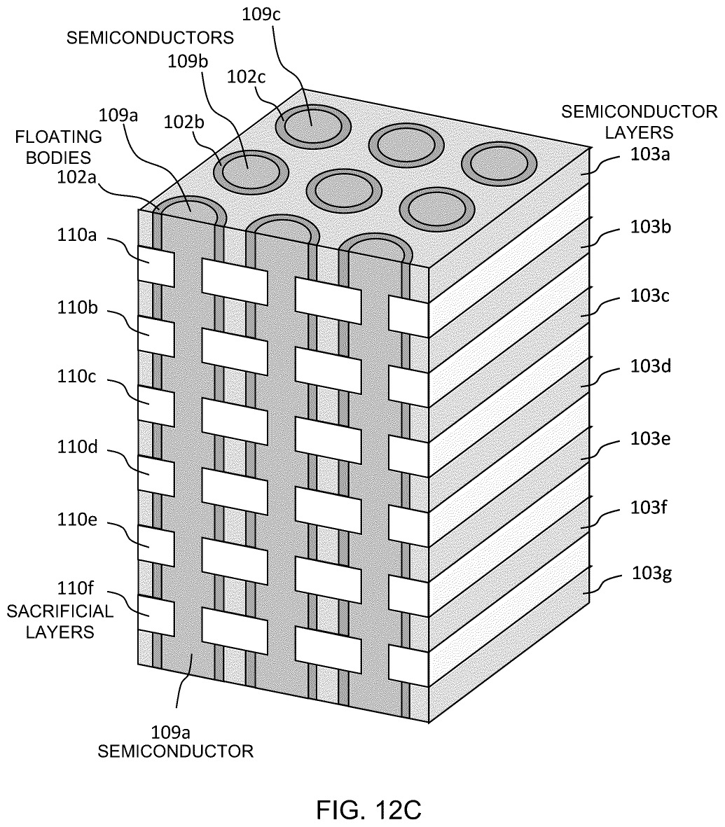

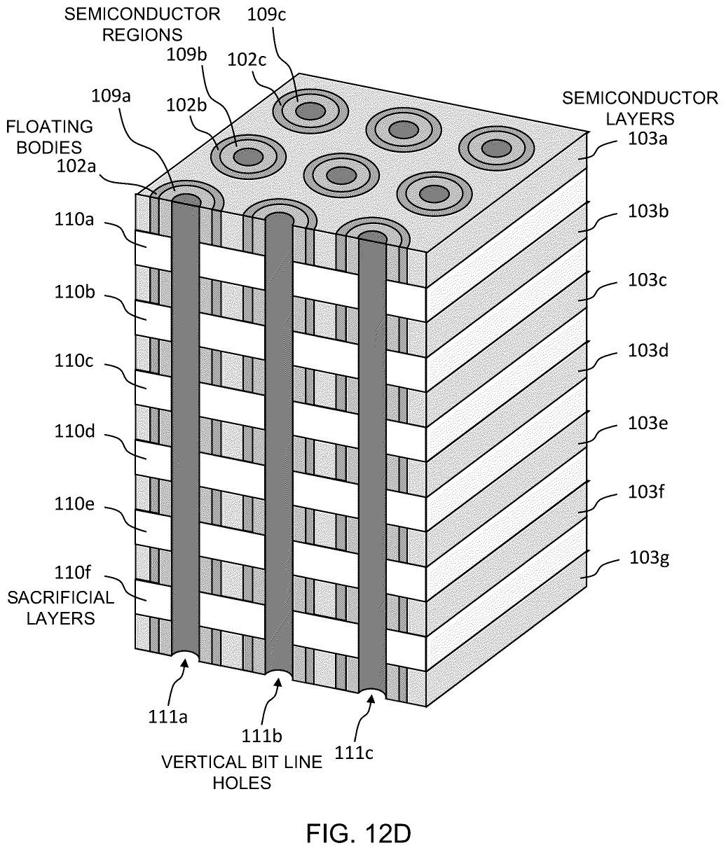

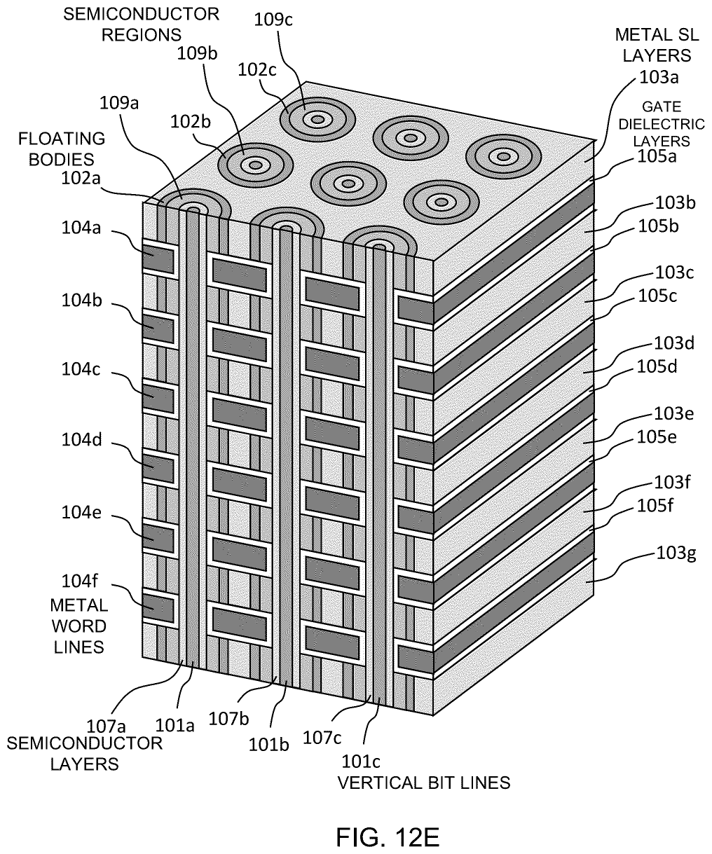

FIGS. 12A-E show another embodiment of brief process steps configured to form an array comprising the cell structure shown in FIG. 1O according to the invention.

FIG. 12A shows an array structure that results after performing the process steps shown in FIGS. 4A-C. The reader is referred to FIGS. 4A-C for a detailed description of the process steps used to form this array structure.

FIG. 12B shows how an isotropic etching process, such as wet etching is performed through the vertical bit line holes, such as bit line holes 111a to 111c to selectively etch the floating bodies, such as floating bodies 102a to 102c to form recesses, such as recesses 114a to 114c. In another embodiment, the floating bodies 102 are formed after the recesses 114 are formed. In this embodiment, after the process steps shown in FIG. 4B are performed, an isotropic etching process, such as wet etching is performed through the vertical bit line holes, such as bit line holes 111a to 111c to selectively etch the semiconductor layers 103a to 103g to form recesses, such as recesses 114a to 114c. Next, an isotropic doping process, such as plasma doping or gas-phase doping is performed to dope the semiconductor layers 103a to 103g with the opposite type of dopants as the semiconductor layers 103a to 103g to form the floating bodies, such as floating bodies 102a to 102c as shown in FIG. 12B.

FIG. 12C shows how a semiconductor material 109, such as semiconductors 109a-c that is different from the material of the floating bodies 102 is deposited by using an appropriate deposition process to fill the vertical bit line holes 111 and the recesses 114. For example, in one embodiment, if the floating bodies 102 are formed of silicon or polysilicon, and the semiconductor material 109 is formed of silicon germanium (SiGe) or silicon carbide (SiC).

FIG. 12D show how an anisotropic etching process, such as dry etching is performed using the sacrificial layers 110a to 110f as hard masks to selectively etch the semiconductor material 109 to re-form the vertical bit line holes 111. Because this etching process is self-aligned, it achieves a high process yield. After the vertical bit line holes 111 are re-formed, the residual of the semiconductor material in the recesses becomes the semiconductor regions 109 (e.g., regions 109a to 109c) that form quantum wells to store electric charge, such as by storing holes, as described with reference to FIG. 1O.

FIG. 12E shows an array structure that results after the process steps shown with reference to FIGS. 4E-I are performed. The reader is referred to FIGS. 4E-I for the detailed description of those process steps. For example, the first sacrificial layers 110 are removed, gate dielectric layers 105 are deposited, the metal word lines 104 are formed, the semiconductor layers 107 are deposited and the vertical bit line 101 are formed. As a result, the array shown in FIG. 12E comprising the floating-body cell structure shown in FIG. 1O is formed.

While exemplary embodiments of the present invention have been shown and described, it will be obvious to those with ordinary skills in the art that based upon the teachings herein, changes and modifications may be made without departing from the exemplary embodiments and their broader aspects. Therefore, the appended claims are intended to encompass within their scope all such changes and modifications as are within the true spirit and scope of the exemplary embodiments of the present invention.

What is claimed is:

1. A memory cell structure, formed by a process of:
alternately depositing multiple semiconductor layers and sacrificial layers to form a stack;
forming vertical bit line holes through the stack using a deep trench process;
forming floating bodies in the semiconductor layers using an isotropic doping process through the bit line holes;
depositing conductor material to fill the bit line holes;
removing the sacrificial layers;
depositing a gate dielectric layer between the semiconductor layers; and
depositing gate material onto the gate dielectric layer.

2. The memory cell structure of claim 1, wherein the isotropic doping process comprises one of plasma doping (PLAD), gas-phase doping, collisional plasma doping, or plasma immersion ion implantation (PIII).

3. The memory cell structure of claim 1, where the floating bodies are formed to have a doping type that is opposite from a doping type of the semiconductor layers.

4. The memory cell structure of claim 1, wherein the bit line conductor comprises one or metal material or polysilicon material.

5. The memory cell structure of claim 1, further comprising an operation of depositing a semiconductor layer before depositing the conductor to fill the bit line holes.

6. The memory cell structure of claim 1, further comprising an operation of using an isotropic doping process through the bit line holes to form drain regions in the floating bodies before depositing the conductor material bit line conductors to fill the bit line holes.

7. A memory cell structure, formed by a process of:
alternately depositing multiple conductor layers and sacrificial layers to form a stack;
forming vertical bit line holes through the stack using a deep trench process;
forming recesses in the conductor layers using an isotropic etching process through the bit line holes;
depositing a semiconductor to fill the bit line holes and recesses to form floating bodies;
removing the semiconductor inside the bit line holes to reform the bit line holes;
depositing conductors to fill the bit line holes;
removing the sacrificial layers;
depositing gate dielectric layers between the semiconductor layers; and
depositing gate material onto the gate dielectric layers.

8. The memory cell structure of claim 7, wherein the isotropic etching process comprises a wet etching process.

9. The memory cell structure of claim 7, wherein the bit line conductor is one of metal or polysilicon.

10. The memory cell structure of claim 7, further comprising an operation of depositing a semiconductor layer in the bit line holes before depositing conductors to fill the bit line holes.

11. The memory cell structure of claim 7, further comprising an operation of using an isotropic doping process through the bit line holes to form drain regions in the floating bodies before depositing the conductors to fill the bit line holes.

12. A memory cell structure, comprising:
multiple semiconductor layers and sacrificial layers alternately depositing to form a stack;
vertical bit line holes formed through the stack;
floating bodies in the semiconductor layers that are formed using an isotropic doping process through the bit line holes;
conductor material deposited to fill the bit line holes;
a gate dielectric layer formed between the semiconductor layers that is deposited after the sacrificial layers are removed; and
gate material that is deposited onto the gate dielectric layer.
